(19) United States
(12) Patent Application Publication
(10) Pub. No.: US 2026/0195063 A1
(43) Pub. Date: Jul. 9, 2026

(54) SEMICONDUCTOR DEVICES, METHODS OF OPERATING SEMICONDUCTOR DEVICES, SYSTEMS AND APPARATUSES

(71) Applicant: Yangtze Memory Technologies Holding Co., Ltd., Wuhan (CN)

(72) Inventors: Yu ZHANG, Wuhan (CN); Zongliang HUO, Wuhan (CN); Lei JIN, Wuhan (CN); Feng XU, Wuhan (CN); Da LI, Wuhan (CN)

(21) Appl. No.: 19/273,079

(22) Filed: Jul. 17, 2025

(30) Foreign Application Priority Data
Jan. 3, 2025 (CN) 202510013495.X

(51) Int. Cl. G06F 3/06

(52) U.S. Cl. CPC G06F 3/064; G06F 3/0604; G06F 3/0679

(57) ABSTRACT

The present disclosure provides a semiconductor device, system, and an operating method thereof. The semiconductor device includes a peripheral circuit and an array of memory cells. The array of memory cells is coupled to the peripheral circuit, and includes a storage zone and a compute-in-memory zone. The compute-in-memory zone includes a plurality of memory banks, the storage zone and any one of the memory banks includes a plurality of memory blocks. The plurality of memory banks are configured to perform a compute-in-memory operation. The plurality of memory blocks in the storage zone are configured to perform a memory operation.

### CROSS-REFERENCE TO RELATED APPLICATIONS

This application claims priority to Chinese Patent Application No. 202510013495.X, filed on Jan. 3, 2025, which is hereby incorporated by reference in its entirety.

### TECHNICAL FIELD

The present disclosure relates to a technical field of semiconductor, and in particular, to semiconductor devices, methods of operating semiconductor devices, systems and apparatuses.

### BACKGROUND

In the end-side application based on the NAND compute-in-memory device, due to the strict requirement for precision of the compute-in-memory device performing a compute-in-memory operation, the manufacturing and use costs are high.

### SUMMARY

The examples of the present disclosure provide semiconductor devices, methods of operating semiconductor devices, systems, and apparatuses.

According to first aspect, an example of the present disclosure provides a semiconductor device, including: a peripheral circuit and an array of memory cells coupled to the peripheral circuit. The array of memory cells includes a storage zone and a compute-in-memory zone. The compute-in-memory zone includes a plurality of memory banks, and the storage zone and any one of the memory banks include a plurality of memory blocks. The plurality of memory banks are configured to perform a compute-in-memory operation. The plurality of memory blocks in the storage zone are configured to perform a memory operation.

In some implementations, the physical address ranges mapped to the memory blocks in the storage zone and the compute-in-memory zone are different and have no intersection.

In some implementations, the peripheral circuit is configured to: configure a memory bank of the plurality of memory banks whose faulty memory blocks have a number greater than a threshold as the storage zone.

In some implementations, the peripheral circuit is configured to: control a target memory bank in the compute-in-memory zone to perform the compute-in-memory operation according to a first address information, wherein the first address information is configured to determine a position of the target memory bank; and control a target memory block in the storage zone to perform the memory operation according to a second address information, wherein the second address information is configured to determine a position of the target memory block.

In some implementations, the peripheral circuit is configured to: control the target memory bank to perform the memory operation according to the first address information when the number of faulty memory blocks in the target memory bank is greater than the threshold.

In some implementations, the peripheral circuit is configured to: configure a first number of memory blocks in the plurality of memory blocks of the memory bank as working memory blocks, and configure a second number of memory blocks as extra memory blocks.

In some implementations, the peripheral circuit is configured to: configure a memory bank of the plurality of memory banks whose faulty memory blocks have a number greater than the second number as the storage zone.

In some implementations, the peripheral circuit is configured to: control target memory blocks in a target memory bank to perform the compute-in-memory operation according to a first address information, wherein the target memory bank is the memory bank in the compute-in-memory zone, a number of the target memory blocks is the first number; and the first address information is configured to determine positions of the target memory bank and the target memory blocks.

In some implementations, the peripheral circuit is configured to: control the target memory blocks in the target memory bank to perform the memory operation according to the first address information when the number of the target memory blocks is less than the first number.

In some implementations, the peripheral circuit is configured to: read data in the compute-in-memory zone and write the data into the storage zone; erase the data in the compute-in-memory zone; and read data in the storage zone and write the data into the compute-in-memory zone.

In some implementations, the data in the compute-in-memory zone includes valid data configured to perform the compute-in-memory operation, and the peripheral circuit is configured to: read the valid data in the compute-in-memory zone and write the valid data into the storage zone; erase data in the compute-in-memory zone; and read the valid data in the storage zone and write the valid data into the compute-in-memory zone.

According to second aspect, an example of the present disclosure provides an operating method of a semiconductor device, including: controlling a target memory bank in a compute-in-memory zone to perform a compute-in-memory operation according to a first address information, wherein the first address information is configured to determine a position of the target memory bank; and controlling a target memory block in a storage zone to perform a memory operation according to a second address information, wherein the second address information is configured to determine a position of the target memory block.

In some implementations, the physical address ranges mapped to memory blocks in the storage zone and the compute-in-memory zone are different and have no intersection.

In some implementations, the method further includes: controlling the target memory bank to perform the memory operation according to the first address information when a number of faulty memory blocks in the target memory bank is greater than a threshold.

In some implementations, the method further includes: reading data in the compute-in-memory zone and writing the data into the storage zone; erasing data in the compute-in-memory zone; and reading the data in the storage zone and writing the data into the compute-in-memory zone.

In some implementations, the data in the compute-in-memory zone includes valid data configured to perform a compute-in-memory operation. The method further includes: reading valid data in the compute-in-memory zone and writing the valid data into the storage zone; erasing data in the compute-in-memory zone; and reading the valid data in the storage zone and writing the valid data into the compute-in-memory zone.

In some implementations, a number of faulty memory blocks in the memory bank of the compute-in-memory zone is less than a threshold.

In some implementations, the memory bank of the compute-in-memory zone includes a first number of working memory blocks and a second number of extra memory blocks.

In some implementations, a number of faulty memory blocks in the memory bank of the compute-in-memory zone is less than the second number.

In some implementations, the controlling the target memory bank in the compute-in-memory zone to perform the compute-in-memory operation according to the first address information includes: controlling target memory blocks in the target memory bank to perform the compute-in-memory operation according to the first address information, wherein the target memory bank is the memory bank in the compute-in-memory zone, a number of the target memory blocks is the first number, and the first address information is configured to determine positions of the target memory bank and the target memory blocks.

In some implementations, the method further includes: controlling the target memory blocks in the target memory bank to perform the memory operation according to the first address information when the number of the target memory blocks is less than the first number.

According to third aspect, an example of the present disclosure provides a system, including a controller and any one of the semiconductor devices according to the first aspect, and the controller is coupled to the semiconductor device.

According to fourth aspect, an example of the present disclosure provides an electronic device, including a host and any one of the systems according to the third aspect, and the host is coupled to the system.

According to fifth aspect, an example of the present disclosure provides a computer storage medium comprising an instruction. The instruction, when executed on a processor, causes the processor to perform the operating method of any one of the semiconductor devices according to the second aspect.

### BRIEF DESCRIPTION OF THE DRAWINGS

In order to more clearly illustrate the technical solutions in the present disclosure, the drawings, which need to be used in some examples of the present disclosure, are briefly introduced below, and it is apparent that the drawings in the following description are merely drawings of some examples of the present disclosure, and other drawings may be obtained by those skilled in the art based on these drawings. In addition, the drawings in the following description may be regarded as schematic diagrams, and do not limit the actual size of the product, the actual flow of the method, the actual timing of the signal, and the like in the examples of the present disclosure.

FIG. 1 is a first schematic structural diagram of an electronic device according to some examples.

FIG. 2 is a second schematic structural diagram of an electronic device according to some examples.

FIG. 3 is a schematic structural diagram of a memory card according to some examples.

FIG. 4 is a schematic structural diagram of a solid state disk according to some examples.

FIG. 5 is a first schematic structural diagram of a semiconductor device according to some examples.

FIG. 6 is a second schematic structural diagram of a semiconductor device according to some examples.

FIG. 7 is a third schematic structural diagram of a semiconductor device according to some examples.

FIG. 8 is a schematic cross-sectional view of a memory string in a semiconductor device according to some examples.

FIG. 9 is a fourth schematic structural diagram of a semiconductor device according to some examples.

FIG. 10 is a third schematic structural diagram of an electronic device according to some examples.

FIG. 11 is a first schematic diagram of a bad block management method according to some examples.

FIG. 12 is a second schematic diagram of a bad block management method according to some examples.

FIG. 13 is a third schematic diagram of a bad block management method according to some examples.

FIG. 14 is a fifth schematic structural diagram of a semiconductor device according to some examples;

FIG. 15 is a sixth schematic structural diagram of a semiconductor device according to some examples.

FIG. 16 is a schematic diagram of threshold voltage distribution according to some examples.

FIG. 17 is a schematic diagram of a method for configuring extra memory blocks in an array of memory cells according to some examples.

FIG. 18 is a seventh schematic structural diagram of a semiconductor device according to some examples.

FIG. 19 is a first schematic structural diagram of a compute-in-memory device according to some examples.

FIG. 20 is a second schematic structural diagram of a compute-in-memory device according to some examples.

FIG. 21 is a third schematic structural diagram of a compute-in-memory device according to some examples.

FIG. 22 is an eighth schematic structural diagram of a semiconductor device according to some examples.

FIG. 23 is a ninth schematic structural diagram of a semiconductor device according to some examples.

FIG. 24 is a first schematic flowchart of an operating method of a semiconductor device according to some examples.

FIG. 25 is a second schematic flowchart of an operating method of a semiconductor device according to some examples.

FIG. 26 is a third schematic flowchart of an operating method of a semiconductor device according to some examples.

FIG. 27 is a fourth schematic flowchart of an operating method of a semiconductor device according to some examples.

FIG. 28 is a fifth schematic flowchart of an operating method of a semiconductor device according to some examples.

FIG. 29 is a sixth schematic flowchart of an operating method of a semiconductor device according to some examples.

### DETAILED DESCRIPTION

The technical solutions in some examples of the present disclosure will be clearly and fully described below with reference to the drawings, and it is apparent that the described examples are only a part of examples of the present disclosure, and are not all examples. All other examples obtained by those skilled in the art based on the examples provided by the present disclosure fall within the scope of the present disclosure.

Unless otherwise required by the context, throughout the specification and claims, the term “comprises” is interpreted as open and inclusive, meaning “comprising, but not limited to”. In the description of the specification, the terms “one implementation”, “some implementations”, “example implementation” “for example,” or “some examples” and the like are intended to indicate that a particular feature, structure, material, or characteristic associated with the implementation or example is comprised in at least one implementation or example of the present disclosure. The schematic representation of the above terms does not necessarily refer to the same implementation or example. Further, the particular feature, structure, material, or characteristic described may be comprised in any suitable manner in any one or more of the implementations or examples.

The terms “first” and “second” are used for descriptive purposes only and are not to be construed as indicating or implying relative importance or implicitly indicating the number of indicated technical features. Thus, features defined by “first”, “second” may explicitly or implicitly comprise one or more of the features. In the description of the examples of the present disclosure, unless otherwise indicated, the meaning of “a plurality of” is two or more.

In describing some examples, “coupled with,” “coupled to,” and “connected to,” and their derivatives, may be used. For example, the term “connected to” may be used in describing some examples to indicate that two or more components are in direct physical contact or electrical contact with each other. As another example, the term “coupled to” may be used in describing some examples to indicate that two or more components are in direct physical contact or electrical contact with each other. However, the term “coupled to” may also mean that two or more components are not in direct contact with each other but still cooperate or interact with each other. The examples disclosed herein are not necessarily limited to the disclosure herein.

“At least one of A, B, and C” has the same meaning as “at least one of A, B, or C”, both comprising the following combinations of A, B, and C: A only, B only, C only, a combination of A and B, a combination of A and C, a combination of B and C, and a combination of A, B, and C.

“A and/or B” comprises the following three combinations: A only, B only, and a combination of A and B.

The use of “adapted to” or “configured to” herein means an open and inclusive language that does not exclude devices suitable or configured to perform additional tasks or operations.

In addition, the use of “based on” means open and inclusive, as in practice, the process, operation, calculation, or other action “based on” one or more of the conditions or values may be based on additional conditions or beyond that value.

The present disclosure is not limited to three-dimensional (3D) NAND semiconductor devices, although 3D NAND semiconductor devices may be used in some examples to illustrate. For example, the techniques disclosed herein may be applied to planar NAND semiconductor devices and NOR semiconductor devices, among others.

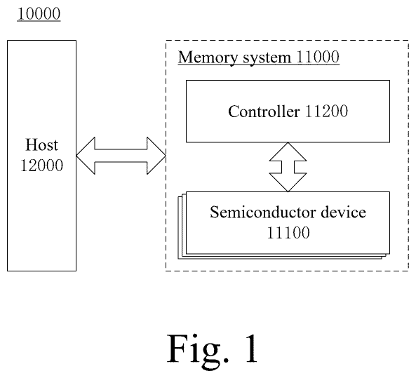

FIG. 1 illustrates a structural diagram of an electronic device 10000 having a semiconductor device in accordance with some aspects. The electronic device 10000 may be a mobile phone (for example, a mobile phone), a desktop computer, a tablet, a notebook computer, a server, a vehicle-mounted device, a game console, a printer, a positioning device, a wearable device (for example, a smart watch, a smart bracelet, smart glasses, etc.), a smart sensor, a mobile power source, a virtual reality (VR) device, an augmented reality (AR) device, or any other suitable electronic device having a storage therein.

As shown in FIG. 1, the electronic device 10000 includes a memory system 11000 and a host 12000. The memory system 11000 includes one or more semiconductor devices 11100 and a controller 11200 coupled to the semiconductor devices 11100.

The host 12000 may be a processor of the electronic device 10000. As an example, the processor may be a chip, for example, a field programmable gate array (FPGA), an application specific integrated circuit (ASIC), a system on chip (SoC), a central processor unit (CPU), a network processor (NP), a digital signal processor (DSP), a microcontroller unit (MCU), a programmable logic device (PLD), an application processor (AP), or other integrated chips.

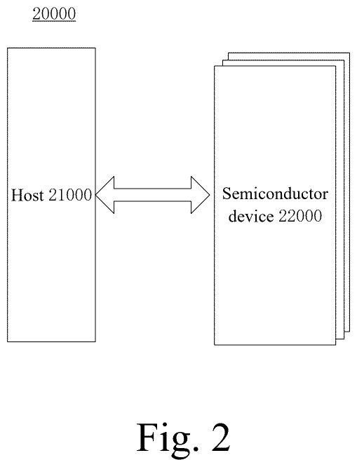

In some implementations, for example, FIG. 2 illustrates a structural diagram of an electronic device 20000 having a semiconductor device in accordance with some aspects, and as shown in FIG. 2, the electronic device 20000 includes a host 21000 and a semiconductor device 22000 (which may also be the semiconductor device 11100 shown in FIG. 1), and the host 21000 is coupled to the semiconductor device 22000. A function of the controller 11200 in the memory system 11000 shown in FIG. 1 is integrated in the host 21000 shown in FIG. 2.

This example is described by taking the electronic device 10000 shown in FIG. 1 as an example.

According to some implementations, the controller 11200 is coupled to the semiconductor device 11100 and the host 12000 and is configured to control the semiconductor device 11100. The controller 11200 may manage data stored in the semiconductor device 11100 and communicate with the host 12000. In some implementations, the controller 11200 is designed to operate in a low duty cycle environment, such as secure digital (SD) cards, compact flash card (CF) cards, universal serial bus (USB) Flash drivers, or other medium used in electronic devices such as personal computers, digital cameras, mobile phones, and the like. In some implementations, the controller 11200 is designed to operate in a high duty cycle environment, such as solid state drives (SSDs) or embedded multimedia cards (eMMCs), which is used as data storage for mobile electronic devices such as smartphones, tablets, personal computers, etc., and enterprise storage arrays.

The controller 11200 may be configured to manage data stored in the semiconductor device 11100 and communicate with an external device, such as the host 12000. The semiconductor device 11100 is controlled to perform corresponding operations, such as performing data read, data erase, and program operations.

In some implementations, the controller 11200 is further configured to process error correction codes (ECCs) related to data read from or written to the semiconductor device 11100.

The controller 11200 may also perform any other suitable function, such as formatting the semiconductor device 11100. The controller 11200 may communicate with an external device (e.g., host 12000) according to a particular communication protocol. For example, the controller 11200 may communicate with an external device through at least one of various interface protocols, such as a USB protocol, a multimedia card (MMC) protocol, a peripheral component interconnect (PCI) protocol, a PCI Express (PCI-E) protocol, an advanced technology attachment (ATA) protocol, a serial-ATA protocol, a parallel-ATA protocol, a small computer system interface (SCSI) protocol, an enhanced small disk interface (ESDI) protocol, an integrated drive electronics (IDE) protocol, a Firewire protocol, etc.

It should be noted that the interface protocol includes at least one of a USB protocol, an MMC protocol, a peripheral component interconnect (PCI) protocol, a PCI Express (PCI-E) protocol, an advanced technology attachment (ATA) protocol, a Serial-ATA protocol, a parallel-ATA protocol, a small computer system interface (SCSI) protocol, an enhanced small disk interface (ESDI) protocol, an integrated drive electronics (IDE) protocol, a Firewire protocol.

The controller 11200 and the one or more semiconductor devices 11100 may be integrated into various types of memory systems 11000, for example, be included in a same package, such as an embedded multimedia card (eMMC), a universal flash storage (UFS) package, an embedded multichip package (eMCP) package, or a UFS-based multichip package (uMCP) package. The eMMC adopts a unified MMC standard interface to package the high-density NAND and the MMC controller in a ball grid array (BGA) packaging chip. The UFS is an advanced version of the eMMC, and is also an array storage module composed of a plurality of flash memory chips and a controller. UFS makes up the defect that eMMC supports only half duplex operation (read and write must be performed separately), and can implement full duplex operation, so that the performance is doubled. The eMCP is packaged by carrying volatile memory, such as static random-access memory (SRAM) or dynamic random-access memory (DRAM), on the eMMC.

In an implementation, the DRAM may be a low power double data rate SDRAM (LPDDR). The uMCP is packaged by carrying volatile memory (such as SRAM or DRAM) on the UFS, and has high performance and high capacity. In an implementation, the DRAM may be an LPDDR. That is, the memory system 11000 may be implemented and packaged into different types of final electronic devices.

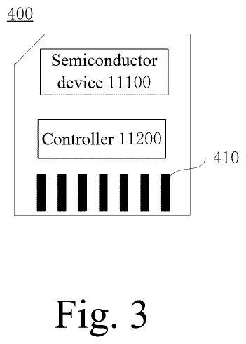

In one example as shown in FIG. 3, the controller 11200 and the single semiconductor device 11100 may be integrated into the memory card 400. The memory card 400 may include a PC Card (PCMCIA, Personal Computer Memory Card International Association), a CF card, a smart media (SM) card, a memory stick, a multimedia card (MMC, RS-MMC, MMCmicro), an SD card (SD, miniSD, microSD, SDHC), UFS, and the like. The memory card 400 may also include a memory card connector 410 that couples the memory card 400 with a host, such as the host 12000 in FIG. 1.

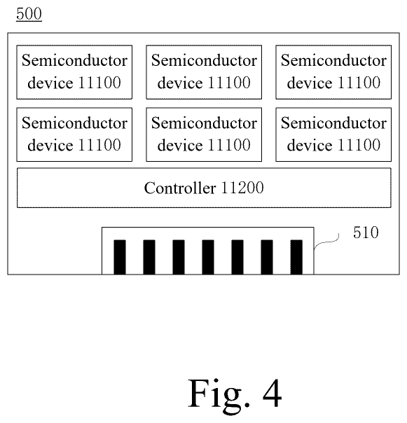

In another example as shown in FIG. 4, the controller 11200 and the plurality of semiconductor devices 11100 may be integrated into the SSD 500. SSD 500 may also include an SSD connector 510 that couples SSD 500 with a host, such as the host 12000 in FIG. 1. In some implementations, at least one of the storage capacity or operating speed of the SSD 500 is higher than that of the memory card 400.

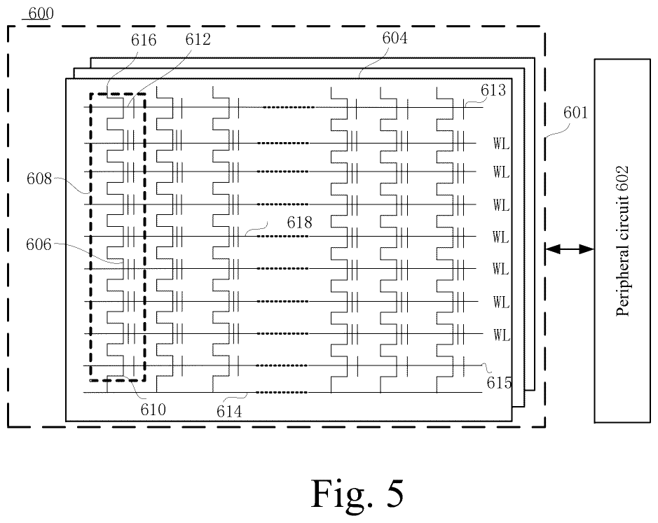

FIG. 5 illustrates a schematic circuit diagram of an example semiconductor device 600 including a peripheral circuit 602, in accordance with some aspects of the present disclosure. The semiconductor device 600 may be an example of the semiconductor device 11100 in FIG. 1. The semiconductor device 600 may include an array of memory cells 601 and a peripheral circuit 602 coupled to the array of memory cells 601. The array of memory cells 601 may be an array of NAND flash memory cells, wherein the memory cells 606 are provided in the form of an array of NAND memory strings 608 each extending vertically above a substrate (not shown). In some implementations, each of the NAND memory strings 608 includes a plurality of memory cells 606 coupled in series and vertically stacked. Each of the memory cells 606 can maintain a continuous analog value, e.g., voltage or charge, depending on the number of electrons captured within the region of the memory cell 606. Each of the memory cells 606 may be a floating gate type of memory cell including a floating gate transistor, or may be a charge trapping type of memory cell including a charge trapping transistor.

In some implementations, each memory cell 606 is a single-level cell (SLC) having two possible storage states (levels) and thus capable of storing one bit of data. In an example, each of the memory cells 606 may be configured to store N bits of data in one of 2N storage states (levels), where N is a natural number greater than 0. The 2N storage states include an erase state and 2N-1 non-erase states. In some implementations, each memory cell 606 is the single-level cell (SLC) that has two possible storage states (levels) and thus may store one bit of data. For example, the first storage state “0” may correspond to a first range of threshold voltages and the second storage state “1” may correspond to a second range of threshold voltages. In some implementations, each memory cell 606 is an xLC capable of storing more than one bit of data in more than four storage states (levels). For example, the xLC can store two bits per cell (multi-level cell (MLC)), three bits per cell (triple-level cell (TLC)), or four bits per cell (quad-level cell (QLC)). Each xLC may be programmed to assume a range of possible nominal stored values. In one example, the MLC may be programmed from an erase state to assume one of three possible program levels by writing one of three possible nominal stored values (e.g., 01, 10, and 11) to the memory cell 606. The fourth nominal stored value may be used for an erase state (e.g., 00).

As shown in FIG. 5, each NAND memory string 608 may also include a source select gate (SSG) transistor 610 at its source end and a drain select gate (DSG) transistor 612 at its drain end. The SSG transistor 610 and the DSG transistor 612 may be configured to activate the selected NAND memory string 608 (column of the array) during read and program operations. In some implementations, the sources of the NAND memory strings 608 in the same memory block 604 are coupled through the same source line (SL) 614 (e.g., common SL). In other words, according to some implementations, all of the NAND memory strings 608 in the same memory block 604 have an array common source (ACS). According to some implementations, a drain of each NAND memory string 608 is coupled to a respective bit line 616 from which data can be read or written via an output bus (not shown). In some implementations, each NAND memory string 608 is configured to be selected or deselected by applying a select voltage or a deselect voltage to a gate of a respective DSG transistor 612 through one or more DSG lines 613 and/or by applying a select voltage or a deselect voltage to a gate of a respective SSG transistor 610 through one or more SSG lines 615.

As shown in FIG. 5, NAND memory strings 608 may be organized into a plurality of memory blocks 604, each of which may have a common source line 614, for example, coupled to an ACS. In some implementations, each memory block 604 is a basic data unit for an erase operation, e.g., all memory cells 606 on the same memory block 604 are erased at the same time. To erase the memory cells 606 in the selected memory block 604, the source line 614 coupled to the selected memory block 604 and the unselected memory blocks 604 in the same plane as the selected memory block 604 may be biased with an erase voltage (Vers), such as high positive bias voltage (e.g., 20V or higher). The memory cells 606 of adjacent NAND memory strings 608 may be coupled by word lines (WL) 618, which select which row of memory cells 606 is affected by read and program operations.

As shown in FIG. 5, the array of memory cells 601 may include an array of the memory cells 606 in a plurality of rows and columns in each memory block 604. According to some implementations, a column of memory cells corresponds to one NAND memory string 608. a plurality of rows of memory cells 606 may be coupled to the word line 618, respectively, and a plurality of columns of memory cells 606 may be coupled to the bit line 616, respectively.

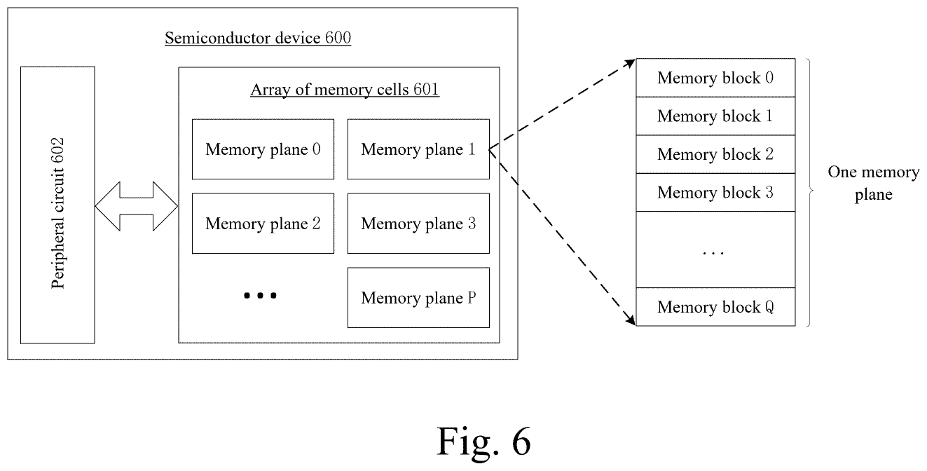

As shown in FIG. 6, the array of memory cells 601 may include a plurality of memory planes (a memory plane 0, a memory plane 1, . . . , a memory plane P), and the memory plane is a minimum unit for implementing the integration of the array of memory cells 601 on the process manufacturing. Each memory plane includes a plurality of memory blocks 604 (a memory block 0, a memory block 1, a memory block 2, a memory block 3, . . . , a memory block Q).

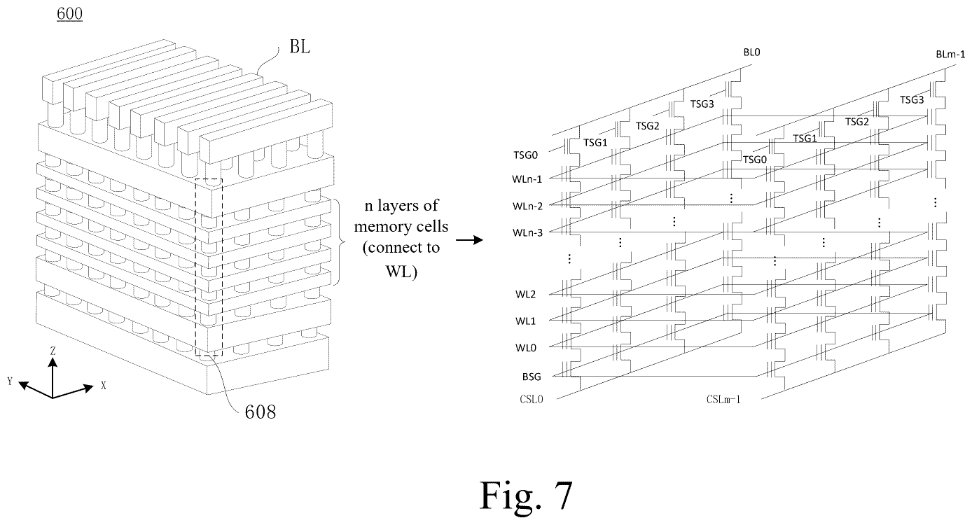

FIG. 7 illustrates a three-dimensional (3D) semiconductor device 600 including a multi-layer stack, in accordance with some aspects of the present disclosure. As shown in FIG. 7, the semiconductor device 600 includes a plurality of memory strings 608 and n layer memory cells (including WL0, WL1, WL2, . . . , WLn-1, WLn-2, WLn-1). The plurality of memory strings 608 included in the semiconductor device 600 are arranged in a direction parallel to the bearing surface of the substrate, and the plurality of memory cells in each memory string 608 are arranged in a direction perpendicular to the bearing surface of the substrate. That is, the plurality of memory cells included in the semiconductor device 600 are arranged in a three-dimensional array on the substrate, and form an array of memory cells.

One end of the memory string 608 is connected to the bit line 616 (including BL0, BL2, . . . , BLm-1), and the other end is connected to a common source line (CSL) or an array common source (ACS). The BSG of the memory string 608 may be coupled to the same CSL, or may be coupled to different CSLs (as shown in FIG. 7, CSLO, . . . , CSLm-1), which is not limited herein.

The memory cells 606 in each memory string 608 are also connected to memory cells 606 in other memory strings by the word line 618. For example, if each memory string 608 may include 64 memory cells 606, the 3D semiconductor device may include 64 word lines 618 WL<63:0>, with each word line 618 connected to a portion of memory cells 606 located in the same layer (e.g., having the same height relative to the substrate). It should be noted that the 64 memory cells 606 are only an example, and the present disclosure is not limited thereto. In some examples, each memory string 608 may include more than 64 memory cells 606, for example, 128, 196, and so on. In the 3D semiconductor device 600, each memory cell 606 connected to the same word line 618 is referred to as a memory page, and all memory strings 608 sharing a group of word lines 618 are referred to as a memory block.

The memory string 608 further includes an upper select transistor connected to the drain of the first memory cell 606, and a lower select transistor connected to the source of the last memory cell 606. The upper select transistor is also referred to as a top select gate (TSG) or DSG transistor, which includes TSG0, TSG1, TSG2 and TSG3. The lower select transistor is also referred to as a bottom select gate (BSG) or SSG transistor.

A gate of the TSG is connected to a drain select line (DSL), a source of the TSG is connected to a drain of the first memory cell 606, and a drain of the TSG is connected to the bit line 616.

A gate of the BSG is connected to a source select line (SSL), a drain of the BSG is connected to a source of the last memory cell 606, and a source of the BSG is connected to a source line.

As shown in FIG. 7, the memory cell 606 in the memory string 608 shares a set of word lines 618 with the memory cells 606 in the other memory strings 608. Assuming that each memory string 608 includes m+1 memory cells 606, the 3D semiconductor device may include m+1 WL: WL0 to WLm, m being an integer greater than 1. Each WL is connected to each memory cell 606 located in the same layer (e.g., having the same height relative to the bearing surface of the substrate). Alternatively, it may be understood that the control gates of each of the memory cells 606 located in the same layer and the gate connection lines between the control gates form one word line 618.

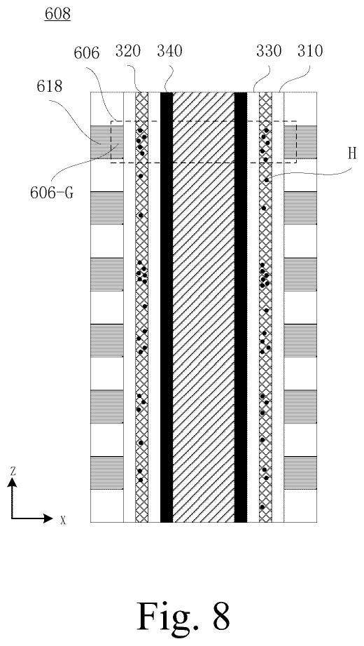

FIG. 8 is a schematic cross-sectional view of a memory string 608 according to an implementation of the present disclosure. The memory string 608 includes a plurality of memory cells 606 disposed in the Z direction. Each memory cell 606 may have the same physical structure. In an example, the memory cell 606 may be a charge trapping type of memory cell. For example, the memory cell 606 may include a gate 606-G, a charge block layer 310, a charge trap layer 320, a tunnel layer 330, and a channel layer 340 (e.g., a poly-si channel). The tunnel layer 330 is located between the charge trap layer 320 and the channel layer 340.

In some implementations, the material of the charge trap layer 320 may include, for example, silicon nitride. The material of the tunnel layer 330 includes silicon oxide, silicon oxynitride, or any combination thereof. The material of the charge block layer 310 includes silicon oxide, silicon oxynitride, a high dielectric constant dielectric, or any combination thereof.

In some implementations, the word line 618 may be physically connected with the gate 606-G of the memory cell 606 on the memory string 608, and may also be physically connected with the gates of the memory cells in other memory strings (not shown) and at the same height (e.g., Z direction) or at approximately the same height.

When performing a program operation on the memory cell 606, the charge trap layer 320 may trap the charge H from the channel layer 340 and through the tunnel layer 330 according to the tunneling effect under voltage control of the gate 606-G. Depending on the number of charges H in the charge trap layer 320 of the memory cell 606, the memory cell 606 may have different threshold voltages, thereby being in different program states.

The charges H stored in the charge trap layer 320 are isolated from other charge trap layers 320 corresponding to different word lines 618, so that longitudinal diffusion of the charge H in the charge trap layer 320 in the direction perpendicular to the substrate (not shown) (Z direction) can be suppressed. The suppression of charge diffusion is advantageous for forming a uniform potential field at the charge trap layer 320, thereby improving the storage reliability of the charge trap layer 320, and further improving the retention property of the semiconductor device 600.

The number of threshold voltage intervals that the memory cell 606 can reach is related to the data size stored in the memory cell 606. For example, the memory cell 606 may be one of an SLC capable of reaching 2 threshold voltage intervals and storing 1 bit data, an MLC capable of reaching 4 threshold voltage intervals and storing 2 bits data, a TLC capable of reaching 8 threshold voltage intervals and storing 8 bits data, or a QLC capable of reaching 16 threshold voltage intervals and storing 16 bits data. The peripheral circuit 602 determines the read data by using the level of the threshold voltage of the memory cell 606.

Referring back to FIG. 5, the peripheral circuit 602 may be coupled to the array of memory cells 601 through bit line (BL) 616, word line 618, source line 614, SSG line 615, and DSG line 613. The peripheral circuit 602 may include any suitable analog, digital, and mixed-signal circuit for facilitating operation of the array of memory cells 601 by applying and sensing at least one of voltage signal or current signal to and from each target memory cell 606 via bit line 616, word line 618, source line 614, SSG line 615, and DSG line 613. The peripheral circuit 602 may include various types of peripheral circuit formed using metal-oxide-semiconductor (MOS) technology.

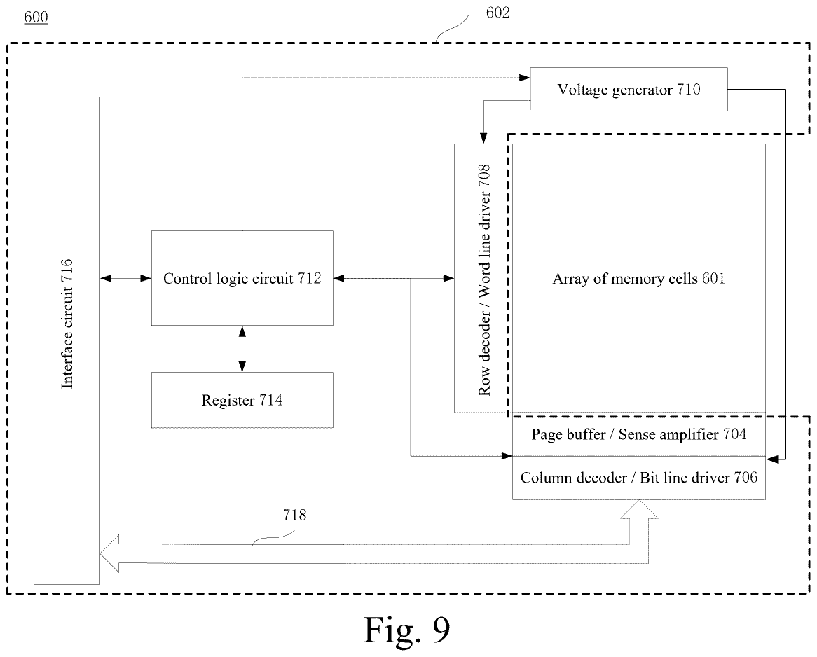

For example, FIG. 9 illustrates some example peripheral circuits including a page buffer/sense amplifier 704, a column decoder/bit line driver 706, a row decoder/word line driver 708, a voltage generator 710, a control logic unit 712, a register 714, an interface circuit (I/F) 716, and a data bus 718. It should be understood that additional peripheral circuit not shown in FIG. 9 may also be included.

The page buffer/sense amplifier 704 may be configured to read and program (write) data from and to the array of memory cells 601 according to control signals from the control logic unit 712. In one example, the page buffer/sense amplifier 704 may perform a program verify operation to ensure that the data has been properly programmed into the memory cell 606 coupled to the selected word line 618. In yet another example, the page buffer/sense amplifier 704 may also sense a low power signal representing a data bit stored in the memory cell 606 from the bit line 616 in a read operation, and amplify the small voltage swing to an identifiable logic level. As described in detail below and consistent with the scope of the present disclosure, in a program operation, the page buffer/sense amplifier 704 may include a memory module (e.g., latch, cache, register, etc.) for temporarily storing a segment of N-bit data received from the data bus 718 and providing the segment of N-bit data to a corresponding target memory cell 606 through a corresponding bit line 616 in each program pass of a multi-pass program operation using the 2N-2N scheme.

The column decoder/bit line driver 706 may be configured to be controlled by the control logic unit 712 and select one or more NAND memory strings 608 by applying a bit line voltage generated by voltage generator 710. The row decoder/word line driver 708 may be configured to be controlled by the control logic unit 712 and select/deselect the memory block 604 of the array of memory cells 601 and select/deselect the word line 618 of the memory block 604. The row decoder/word line driver 708 may also be configured to drive the word line 618 using the word line voltage generated by the voltage generator 710. In some implementations, the row decoder/word line driver 708 may also select/deselect and drive SSG line 615 and DSG line 613. The voltage generator 710 may be configured to be controlled by the control logic unit 712 and generate word line voltage (e.g., read voltage, program voltage, pass voltage, local voltage, verify voltage, etc.), bit line voltages, and source line voltages to be provided to the array of memory cells 601.

The control logic unit 712 may be coupled to each peripheral circuit described above and configured to control operation of each peripheral circuit. The register 714 may be coupled to the control logic unit 712 and include a status register, a command register, and an address register for storing status information, command operation code (OP), and command address for controlling operation of each peripheral circuit. The interface circuit 716 may be coupled to the control logic unit 712 and act as a control buffer to buffer the control command received from the host (e.g., the host 2000 in FIG. 1) and forward it to the control logic unit 712 and buffer status information received from the control logic unit 712 and forward it to the host. The interface circuit 716 may also be coupled to the column decoder/bit line driver 706 via a data bus 718, and act as a data input/output (I/O) interface and a data buffer to buffer and forward data to and from the array of memory cells 601.

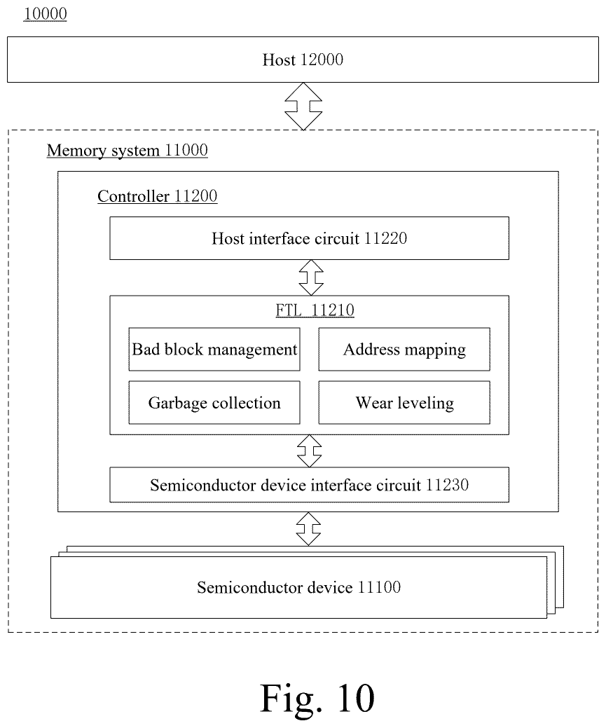

In practical applications, in the manufacturing and subsequent use of the NAND semiconductor device, in order to ensure stable and reliable operation of the NAND semiconductor device, the controller 11200 may be further configured to manage various functions related to data stored in or to be stored in the semiconductor device 11100, including but not limited to bad block management, garbage collection, logical-to-physical address translation, wear leveling, and the like. As shown in FIG. 10, a firmware system: a flash translation layer (FTL) 11210 may be implemented in the controller 11200. The performance, reliability, and durability of the memory system 11000 (e.g., SSD) depend on the implementation of the algorithm of the FTL 11210. The FTL 11210 may include address mapping, garbage collection, wear leveling, bad block management, power failure recovery, and the like. The controller 11200 further includes a host interface circuit 11220 and a semiconductor device interface circuit 11230. The host interface circuit 11220 is configured to couple the host 12000 with the FTL 11210. The semiconductor device interface circuit 11230 is configured to couple the FTL 11210 with the semiconductor device 11100. The semiconductor device interface circuit 11230 includes a plurality of semiconductor devices 11100 (e.g., a semiconductor device 0, a semiconductor device 1, a semiconductor device 2, . . . , a semiconductor device N, etc.).

Due to the first erase and then write characteristics of the semiconductor device 11100, such as the NAND semiconductor device, for the data writing of the same logical address, it cannot be modified on the basis of the physical address of the original stored data, and only the new physical address can be found to write the updated data. Thus, the FTL 11210 needs to maintain a mapping table of a logical address to a physical address, and continuously record the mapping relationship between the logical address accessed by the host and the physical address in the NAND semiconductor device. For the data that has been updated, the data of the original physical address become invalid data, which also occupy the storage space of the NAND semiconductor device. If these invalid data are not processed, the storage space of the NAND semiconductor device will be quickly exhausted. In this regard, the FTL 11210 will perform another important function: garbage collection (GC).

The garbage data is randomly dispersed in each memory block in the NAND semiconductor device, instead of being concentrated in certain memory blocks. In order to improve the efficiency of garbage collection, the memory block with fewer valid data or more invalid data can be selected for collection. Because the valid data is few, the data to be moved is few, so that the speed of emptying the memory blocks is fast, and the cost is low.

In an example, for a NAND semiconductor device, a basic unit for erasing is a memory block, one memory block includes a plurality of physical addresses. Before garbage collection, data in an address storing valid data in the memory block (for example, a source memory block) that is selected to be collected needs to be moved to another idle memory block (target memory block), and then an erase operation is performed on the source memory block.

For example, the memory block after the erase operation is performed is in an erase state or an idle state, and may be marked as a free memory block, and may continue to be configured to perform a corresponding operation, such as performing a program operation on the free memory block.

In addition, since there is an upper limit on the number of program/erase times that can be performed on a memory block in the NAND semiconductor device, the memory block has a certain lifetime, and if relevant operations such as data writing and data erasing are frequently performed on certain memory blocks, these memory blocks can be quickly damaged, thereby reducing the available space of the NAND. When the available space is reduced to a certain threshold, the NAND semiconductor device will be considered damaged. To extend the lifetime of the NAND semiconductor device, the FTL 11210 needs to evenly distribute data writing and data erasing onto each memory blocks, e.g., wear leveling. Even under the processing of a wear leveling algorithm, a damaged memory block will eventually appear as the memory block wears constantly. The damaged memory block may be replaced with a good memory block in an over provision (OP) in the NAND semiconductor device, or may be skipped during data writing, and this process is called bad block management.

Bad block management includes the management for factory bad blocks (FBB) and grown bad blocks (GB).

Factory bad blocks are caused by limitations or accidental factors in the manufacturing process during the production of NAND semiconductor devices. They are identified and marked in the production stage, and when a NAND semiconductor device is used, the mark in the block of the NAND semiconductor device needs to be scanned first, the bad blocks marked by the manufacturer are picked out, and a bad block table (BBT) is generated. In subsequent use, the blocks within the bad block table will not be selected to avoid causing data errors or loss at the client end.

Grown bad blocks, which are different from the factory bad blocks, are gradually formed during normal use of the NAND semiconductor device. This is mainly because frequent erase and write operations result in physical wear of the memory cells, thereby causing data read/write/erase errors. The present of such bad blocks is a reflection of the inherent characteristics of the NAND semiconductor device technology, needs to be dynamically checked and managed through the BBM mechanism, when it is detected that the current memory block becomes a bad block, the memory block cannot be selected and used again, and is recorded into the BBT.

In some examples, for the grown bad blocks, with the use of a semiconductor device, some good memory blocks may become faulty memory blocks during use with the wear of the semiconductor devices. There are mainly the following cases: (1) when performing a data erasing operation, returning to an erase failure state. (2) when performing a data writing operation, returning to a write failure state. (3) when performing a data reading operation, if there are too many data errors and the ECC range is exceeded, and after various ways of error checking and correction, such as by performing a read retry, a low density parity check code (LDPC), or by performing a redundant array of independent disks (RAID), the data is still uncorrectable. When any one of the above three cases occurs, it is considered that the current memory block becomes the faulty memory block, and is recorded into the BBT, and is no longer selected for performing the corresponding operation.

The bad block management includes two management policies, one is a skip policy, and the other one is a replace policy.

For the skip policy, according to the established BBT, the user skips a bad block registered in the table upon encountering the bad block and write a next memory block when performing a data writing operation.

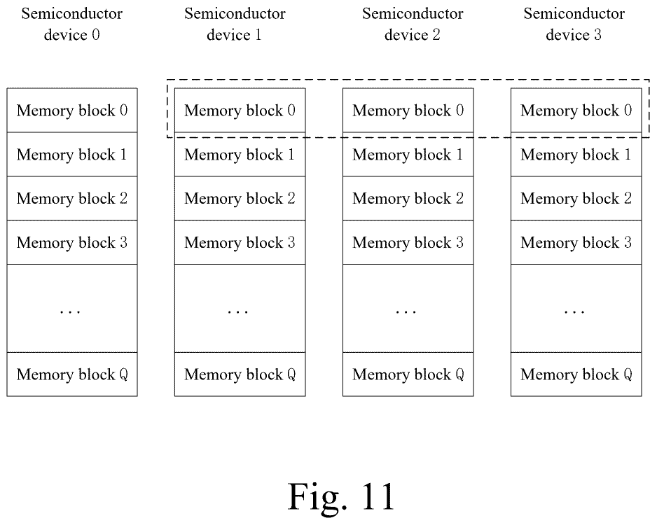

FIG. 11 shows 4 semiconductor devices (a semiconductor device 0, a semiconductor device 1, a semiconductor device 2, a semiconductor device 3) in the memory system 11000, and the stored data are sequentially written into the 4 semiconductor devices (the semiconductor device 0, the semiconductor device 1, the semiconductor device 2, the semiconductor device 3). When the parallel memory blocks are selected, the number of memory blocks selected by each semiconductor device is the same, and according to the bad block table of the user, if the memory block 0 of the semiconductor device 0 is a bad block, the bad block is not added to the parallel memory block stripe, the memory block 0 of the semiconductor device 1, the memory block 0 of the semiconductor device 2 and the memory block 0 of the semiconductor device 3 form a parallel block stripe.

For the skip policy, a bad block is skipped when encountered, the semiconductor device in which the current bad block is located is not used, and the semiconductor device in which the remaining good memory block is located is used to build a parallel block.

An advantage of the skip policy is that the management is simple, and a bad block is skipped when encountered, but the disadvantage is that the performance is unstable. If N semiconductor devices are concurrent, the parallelism of the system may fluctuate between 1 and N, and the performance may not be guaranteed to be stable when N dies are concurrent.

For the replace policy, which is different from the skip policy, a memory block in each die is divided into a main memory block and an extra memory block, wherein the extra memory block is configured to replace a faulty memory block in the main memory block. When a bad block is found on a certain die, the replace policy replaces the faulty memory block in the main memory block with a certain good memory block in the extra memory block in the die. That is, under the replace policy, after encountering the faulty memory block, another available idle block is found in the extra memory block of the current die, and is written onto the replacement block instead of skipping the die.

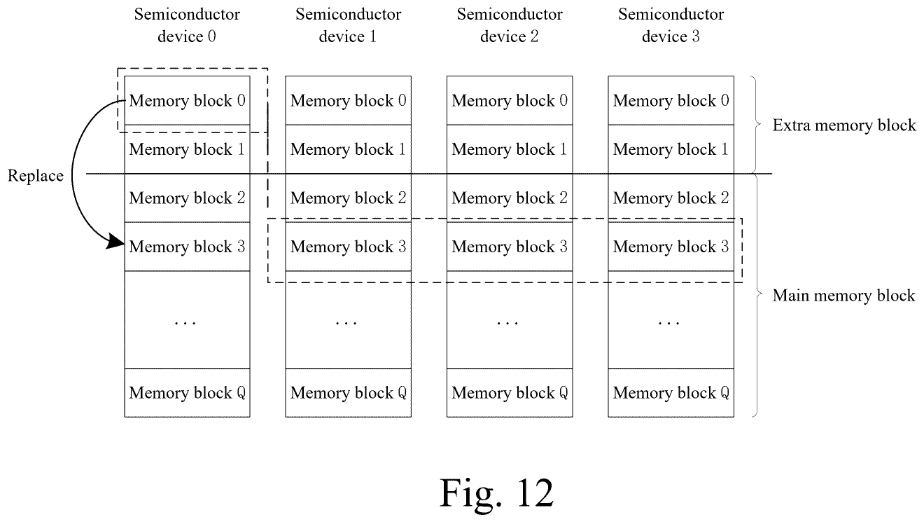

In an example, FIG. 12 shows 4 semiconductor devices (a semiconductor device 0, a semiconductor device 1, a semiconductor device 2, a semiconductor device 3) in the memory system 11000, and the stored data are sequentially written into 4 semiconductor devices (the semiconductor device 0, the semiconductor device 1, the semiconductor device 2, and the semiconductor device 3). If the memory block 3 of the semiconductor device 0 is a bad block, the faulty memory block 3 of the semiconductor device 0 may be replaced with the memory block 0 (or the memory block 1) in the extra memory block in the semiconductor device 0. The memory block 0 of the semiconductor device 0, the memory block 3 of the semiconductor device 1, the memory block 3 of the semiconductor device 2, and the memory block 3 of the semiconductor device 3 then form a parallel block stripe.

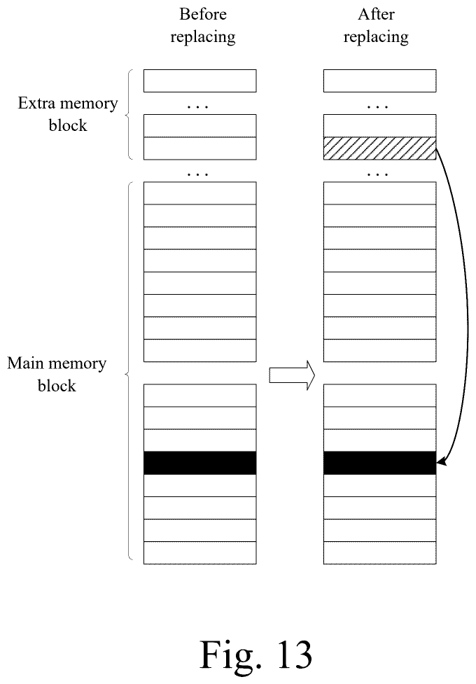

As shown in FIG. 13, a faulty memory block (a black block in the figure) in the main memory block is replaced with a memory block (a block filled with a twill in the figure) in the extra memory block.

Replace policy exhibit significant advantages in ensuring that N dies operate simultaneously, and improving performance stability. At the same time, the policy is not constrained by the physical address for the supplementary operation of the FBB/GBB, and can flexibly map the extra memory block to any position of the logical address space to quickly replace the damaged memory block.

However, although the replace policy is flexible, when the physical address of the faulty memory block is far away from the physical address of the memory block used for replacement, due to the parasitic resistance of the semiconductor device, the longer power supply wiring path can introduce additional voltage drop, making the voltage drop more severe, and significantly exacerbating the voltage drop (IR Drop) problem, which affects the performance of the NAND semiconductor device.

Voltage drop, which is an inevitable voltage loss phenomenon when current passes through a resistor, is particularly critical in NAND semiconductor devices. Particularly when performing large-scale data read, write, or erase operations, current demand spikes, as the positions of memory cells in the array vary, because the parasitic resistances vary at different positions. For cells at the distal end of the array, elements such as metal wires, transistors and the like in the chip generate significant voltage loss due to the resistance effect. This voltage drop not only affects the voltage stability of each region inside the NAND semiconductor device, but also can directly weaken the overall performance and functional reliability of the chip. If the voltage drop causes insufficient voltages for data read, write, or erase operations, the corresponding operation is unsuccessful.

Further, there is a close association between the position of the memory block in the NAND semiconductor device and the voltage drop. Due to differences in physical layout of the memory blocks at different positions, and in particular, different lengths of the additional wirings are different, causing the changes in current distribution and the resistance effect, so that each memory block is affected differently when the voltage drop happens. The different effects of voltage drop may finally be reflected on the degradation of the read/write performance and the fluctuation of stability of the memory block.

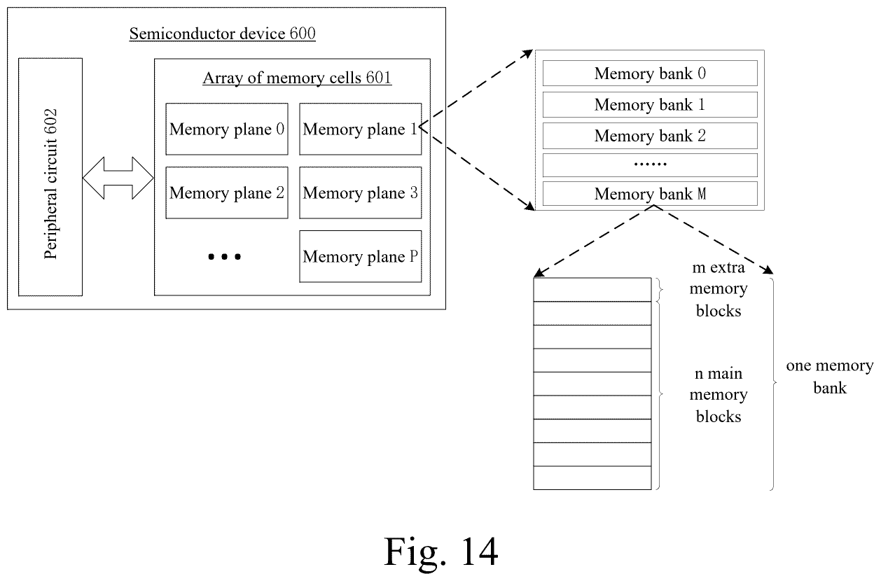

To solve one or more of the above problems, a structure of the array of memory cells 601 shown in FIG. 6 may be improved, as shown in FIG. 14, a memory block in a memory plane is configured to a plurality of memory banks, at a level of a memory bank, each memory bank includes m+n memory blocks, any n memory blocks in m+n memory blocks are used as main memory blocks (or working memory blocks), and when a corresponding operation (such as a write operation, a read operation, an erase operation, or a compute-in-memory operation, and the like) is performed at the level of the memory bank, n memory blocks are selected in each memory bank to perform a corresponding operation. Any m memory blocks in the m+n memory blocks are used as extra memory blocks to replace the faulty memory blocks in the memory bank, to ensure that there are at least n normal memory blocks in each memory bank. If a number of normal memory blocks in the memory bank is less than n, the memory bank will be marked as a faulty memory bank and will not be configured to perform a corresponding data operation.

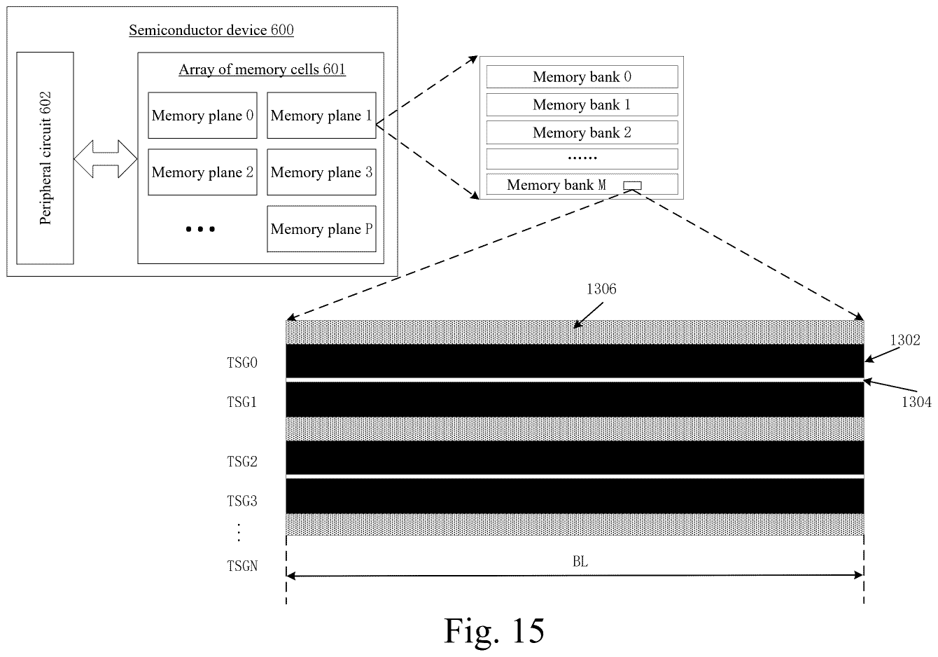

As shown in FIG. 15, six memory planes (a memory plane 0, a memory plane 1, a memory plane 2, a memory plane 3, a memory plane 4, and a memory plane 5) in the array of memory cells 601 are shown, and each memory plane includes a plurality of memory banks (a memory bank 0, a memory bank 1, a memory bank 2, . . . , a memory bank M). Each memory bank includes a plurality of TSGs (TSG0, TSG1, TSG2, TSG3, . . . ,TSGN), each TSG is coupled with the gate-line 1302 of the upper select transistor of memory string 608, and a TSG Slit 1304 is formed between the TSGs to cut off (or isolate) the TSGs. A gate-line slit 1306 is formed at a position adjacent to the TSG, and is configured to cut off (or isolate) the metal layer corresponding to the gate line of the upper select transistor of the memory string 608 in the array of memory cells 601.

In an example, the TSG may be a Coarse TSG. Each memory bank may include a 16 KB bit line BL.

In order to limit the size of the relative physical address span between the memory blocks in the same memory bank, when the memory block is configured for each memory bank during designing, it is ensured that a physical distance between any two of the m+n memory blocks included in each memory bank is less than a threshold. Meanwhile, it is ensured that a difference between a physical address of any faulty memory block and a physical address of any normal memory block in a same memory bank is less than a threshold.

In the solution disclosed in present disclosure, in each memory bank, it is not necessary to specify which m memory blocks in the memory bank are m extra memory blocks, or which n memory blocks in the memory bank are n main memory blocks. When in use, n normal memory blocks are selected from (n+m) memory blocks in each memory bank to perform a corresponding operation. By distributing the extra memory blocks into each memory bank, the relative physical address spans between the memory blocks in the same memory bank are relatively small, and relatively fixed, so that the variation of the current distribution and the resistance effect can be reduced, and the corresponding threshold voltage (Vt) distribution is more converged.

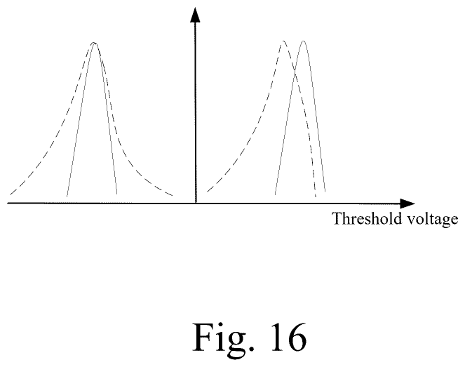

FIG. 16 shows any two of the multiple program states, wherein the threshold voltage distribution shown by the dashed line corresponds to the threshold voltage distribution before the present solution is implemented, and the threshold voltage distribution shown by the solid line corresponds to the threshold voltage distribution after the present solution is implemented.

According to the solution disclosed by the present disclosure, by reducing the influence of the voltage drop on the read-write performance of the memory block, the read-write performance, stability and reliability of the memory block are improved. Meanwhile, since the n working memory blocks are selected from the m+n memory blocks, the corresponding data operations are relatively evenly distributed to the n memory blocks in the m+n memory blocks, so that wear leveling is achieved, and the lifetime of the semiconductor device is prolonged.

In some scenarios, a probability that a bad block is generated in the semiconductor device 600 may be relatively small, a probability that a bad block is generated in a plurality of memory banks is even smaller, and if m extra memory blocks are configured for each memory bank, the utilization of the memory space of the semiconductor device may be relatively low, resulting in issues such as a relatively high cost of the hardware material.

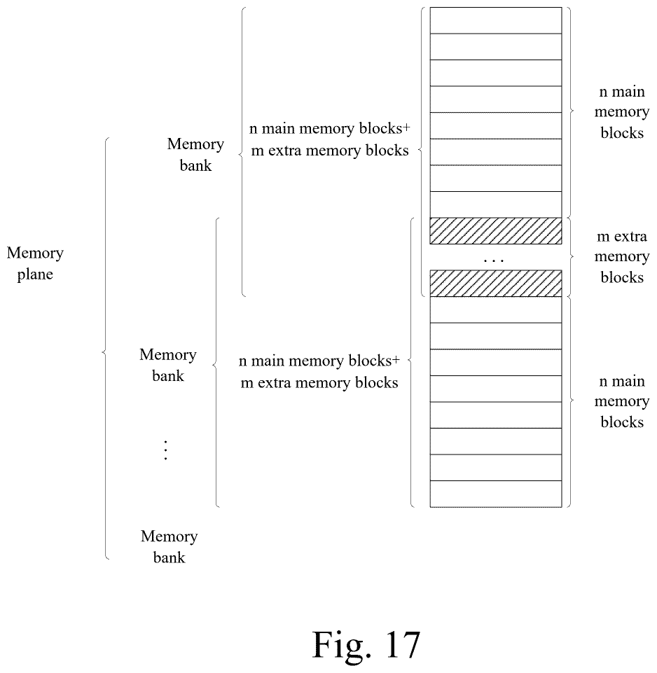

In order to improve the utilization efficiency of the storage space to reduce the cost of the hardware material, in some implementations, as shown in FIG. 17, the array of memory cells 601 may be configured such that at least two memory banks share m extra memory blocks (m is greater than or equal to 1). Any one of the m extra memory blocks can only be configured to replace a faulty memory block in one memory bank.

As shown in FIG. 14 or FIG. 17, the extra memory block in the memory bank is also used as a system block of a data cache, and is configured to store a system file or a temporarily store data. Since the lifetime of the extra memory block is very easy to run out, more space needs to be reserved. When space is reserved at the level of the memory bank, the larger the level is, the poorer design flexibility is. In addition, when the faulty memory blocks within a memory bank is greater than a threshold, the memory bank is marked as a faulty memory bank, and is not configured to perform a corresponding data operation, thereby causing space waste.

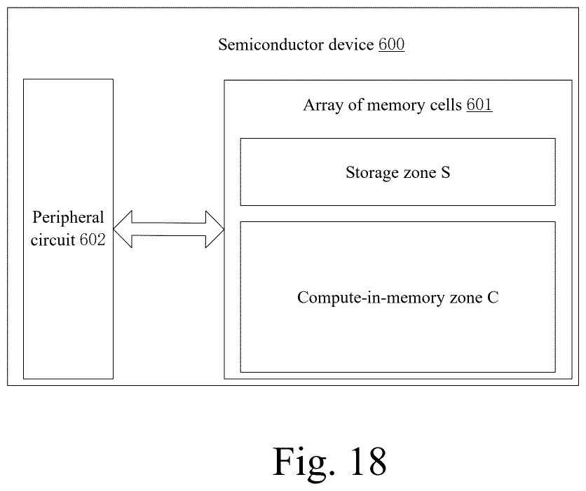

In order to solve one or more of the above problems, the present example provides a semiconductor device, as shown in FIG. 18, the array of memory cells 601 includes a storage zone S and a compute-in-memory zone (CIM zone) C. The compute-in-memory zone C includes a plurality of memory banks, and the storage zone S and the memory bank each include a plurality of memory blocks. The plurality of memory banks are configured to perform a compute-in-memory operation. The plurality of memory blocks in the storage zone S are configured to perform a memory operation.

In some implementations, in the semiconductor device 600 shown in FIG. 18, the memory blocks in the array of memory cells 601 shown in FIG. 6 may be separately divided into a part of the memory blocks as a storage zone S, which is used as a system block or a cache for temporarily storing data, to perform a memory operation. The other part of the memory block is configured as shown in FIG. 14, and is used as the compute-in-memory zone C, and is configured to perform a compute-in-memory operation, for example, perform storage of a model parameter or weight data and perform a corresponding inference operation (for example, a convolution operation).

By dividing the semiconductor device into the storage zone S and the compute-in-memory zone C, the storage function is clearly separated from the compute-in-memory function. As a result, the memory operation and the compute-in-memory operation can be carried out independently without interfering with each other, so that the overall operation efficiency and performance are improved.

In addition, when the semiconductor device 600 is used as a compute-in-memory (CIM) device, in addition to being used as a memory bank working in the compute-in-memory zone C, an additional other memory banks or memory blocks are required to be used as a system block or a reserved space for performing garbage collection normally. When a space for normal garbage collection is reserved in the storage zone S or used as a system block, it may be reserved at a level of the memory block, and it is not necessary to reserve at the level of the memory bank. The configuration of the memory block is flexible, and the flexibility is higher, which facilitates saving area and reducing the manufacturing and use costs.

At the same time, the memory operation is performed in the storage zone S, and the requirement for reliability is lower. As shown in FIG. 16, the requirement for the threshold voltage convergence is less than that of the compute-in-memory zone C, and thus the memory block in the storage zone S has a longer lifetime, the required reserved space requirement is smaller, and thereby saving area and reducing the manufacturing and use costs.

In some examples, the compute-in-memory zone C may be configured to perform a compute-in-memory operation. At present, most computation platforms are based on a von Neumann architecture, which is computationally centric, wherein a compute module and a storage module are separated, and the two coordinate to complete data operation and access. However, because the compute module (for example, the processor, which may be disposed in the controller 11200 or the host 12000, not shown in the figure) is designed to mainly improve the computation speed, while the storage module pays more attention to capacity improvement and cost optimization, and the performance is mismatched between “storage” and “compute”, which leads to problems such as low memory access bandwidth, long latency, high power consumption and the like, that is, the commonly referred the “storage wall” and the “power consumption wall”. The more intensive the memory access is, the more serious the problem of “wall” is, and the more difficult it is to improve computing power. With the rapid rise of memory access intensive applications represented by artificial intelligence, such as a convolutional neural network (CNN), a recurrent neural network (RNN), and the like, memory access latency and power consumption overheads cannot be ignored, and the reform of a computing architecture is particularly urgent.

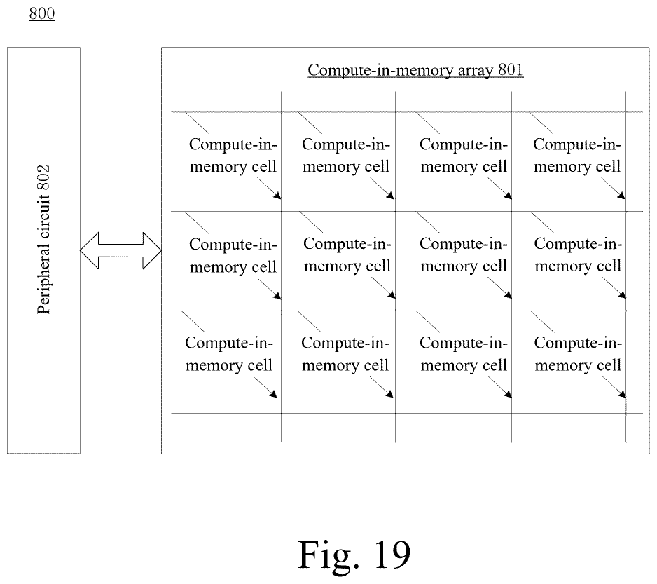

The core of the compute-in-memory architecture, which is a new computing architecture, is to completely fuses the storage and computation, can effectively overcome the bottleneck of the von Neumann architecture, and can achieve the order of magnitude improvement in computational energy efficiency. For the compute-in-memory, in the chip design process, the memory cell and the computation unit are no longer distinguished, and the fusion of the storage and computation is truly realized. The essence of the compute-in-memory is to use physical characteristics of different storage media to redesign the storage circuit to have both the computation and storage capacity, thereby directly eliminating the boundary between “storage” and “computation”, and achieving the goal of improving computing energy efficiency by orders of magnitude. FIG. 19 shows a structural diagram of a compute-in-memory device 800, which includes a compute-in-memory array 801 and a peripheral circuit 802 to which the compute-in-memory array 801 is coupled. The compute-in-memory array 801 is configured to store weight matrix data, the compute-in-memory array includes compute-in-memory cells arranged in rows and columns, and these cells may perform various computation operations, such as matrix operation and vector operation, according to a preset algorithm.

Compared with the von Neumann architecture, the compute-in-memory architecture has the advantages of high operation speed, low power consumption, high integration density and the like, the compute-in-memory fuses the computation function into the memory cell, so that the frequent transportation of the data between the data storage module and the compute module is reduced, the delay of data transmission is reduced. In addition, the compute-in-memory integrates the computation and storage functions on the same chip, and thus the external connection and wiring requirements are reduced, so that the integration level of the chip is higher, and the chip can be applied to smaller and lighter electronic device.

An artificial intelligence algorithm represented by a neural network relates to various tensor and vector computation, wherein most representative operators are matrix vector multiplication, and these operators usually have the characteristics of large data amount, large computing amount and high parallelism requirement. When an artificial intelligence algorithm is executed by a processor in a computing platform based on a von Neumann architecture, due to the separation of storage and computation, a large amount of data transportation exists between the memory and the arithmetic unit, causing huge power consumption and delay overhead, which results in that the power consumption of data transportation is far higher than that of the computing power consumption, and this becomes a bottleneck of the development of the von Neumann architecture accelerator. The core idea of the compute-in-memory technology is to fuse the memory with the arithmetic unit together, by storing the relatively fixed weight matrix data in the memory and inputting the input feature vector into the array, the matrix-vector multiplication computation is performed in the memory, so that the transportation of a large amount of weight data is effectively avoided while the high parallel data access and computation are completed, thereby achieving the purpose of improving the operation speed and the energy efficiency, and therefore the compute-in-memory is very suitable for accelerating the matrix and vector operation in the artificial intelligence algorithm.

In some examples, the compute-in-memory array 801 may be configured to perform a matrix-vector multiplication operation as shown in the formula (1), where V_{IN0}, V_{IN1}, . . . , V_{INN} represent the operation data (or input vector) input the compute-in-memory array 801, taking an image recognition application as an example, and the operation data may be image feature information. W₀₀, W₀₁, . . . , W_{0M}; W₁₀, W_{1M}; . . . , W_{1M}; . . . ; W_{N0}, W_{N1}, . . . , W_{NM} etc. represent the weight matrix data stored in the compute-in-memory array 801, which is composed of weight data (for example, for flash memory, NAND or NOR can be characterized by the threshold voltage of the memory cell, and for the RRAM memory, it can be characterized by the conductance of the memory cell, and this example takes NAND as an example for illustration). Formulas (2), (3) and (4) are used for representing an operation result of multiplying and accumulating the operation data and the weight matrix data.

$$Formula ( 1 )$$

$$[ {V}_{IN 0} , {V}_{IN 1} , … , {V}_{INN} ] * [ \begin{matrix}{w}_{00} , {w}_{01} , … , {w}_{0 M} \\ {w}_{10} , {w}_{11} , … , {w}_{1 M} \\ … \\ {w}_{N 0} , {w}_{N 1} , … , {w}_{NM}\end{matrix} ] = [ {I}_{D 0} , {I}_{D 1} , … , {I}_{D M} ]$$

$${I}_{D 0} = {V}_{IN 0} * {w}_{00} + {V}_{IN 1} * {w}_{10} + … + {V}_{INN} * {W}_{N 0} \qquad Formula ( 2 )$$

$${I}_{D 1} = {V}_{IN 0} * {w}_{01} + {V}_{IN 1} * {w}_{11} + … + {V}_{INN} * {W}_{N 1} \qquad Formula ( 3 )$$

$$…$$

$${I}_{D M} = {V}_{IN 0} * {W}_{0 M} + {V}_{IN 1} * {W}_{1 M} + … + {V}_{INN} * {W}_{N M} \qquad Formula ( 4 )$$

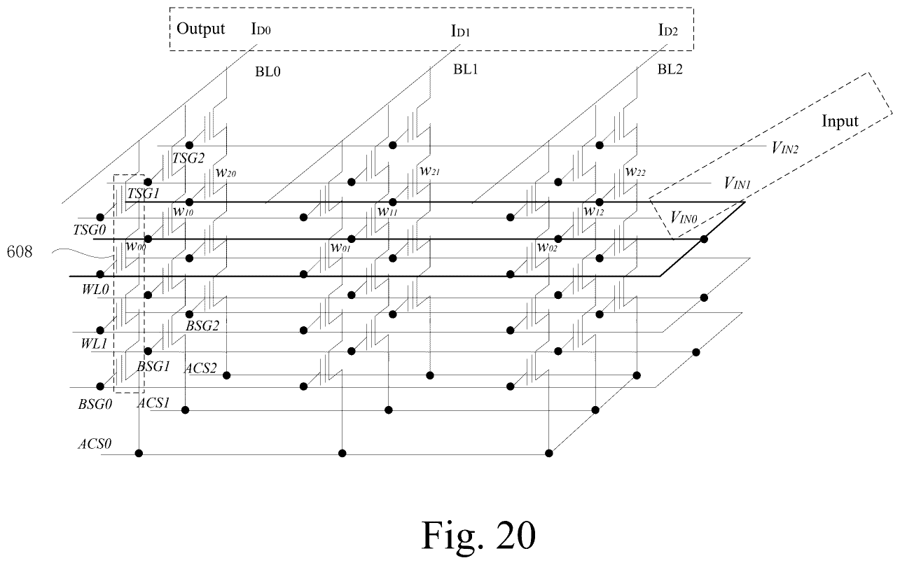

FIG. 20 shows an example of a matrix-vector operation when the semiconductor device 600 is used as a compute-in-memory device 800, as shown in Formula (5) to Formula (9):

$$[ \begin{matrix}{V}_{IN 0} & {V}_{IN 1} & {V}_{IN 2}\end{matrix} ] * [ \begin{matrix}{w}_{00} & {w}_{01} & {w}_{02} \\ {w}_{10} & {w}_{11} & {w}_{12} \\ {w}_{20} & {w}_{21} & {w}_{22}\end{matrix} ] = [ \begin{matrix}{I}_{D 0} & {I}_{D 1} & {I}_{D 2} ]\end{matrix} \qquad Formula ( 5 )$$

$${I}_{D 0} = {V}_{IN 0} * {w}_{00} + {V}_{IN 1} * {w}_{10} + {V}_{IN 2} * {w}_{20} \qquad Formula ( 6 )$$

$${I}_{D 1} = {V}_{IN 1} * {w}_{01} + {V}_{IN 1} * {w}_{10} + {V}_{IN 1} * {w}_{20} \qquad Formula ( 7 )$$

$${I}_{D 2} = {V}_{IN 0} * {w}_{01} + {V}_{IN 1} * {w}_{11} + {V}_{IN 2} * {w}_{21} \qquad Formula ( 8 )$$

$${I}_{D 2} = {V}_{IN 0} * {w}_{02} + {V}_{IN 1} * {w}_{12} + … + {V}_{IN 2} * {w}_{22} \qquad Formula ( 9 )$$

wherein the process of writing the weight data w₀, W₀₁, W₀₂; W₁₀, W₁₁, W₁₂; W₂₀, W₂₁, W₂₂ into the semiconductor device 600 is completely consistent with the program process of the array of memory cells 601. The operation data (or input vector) V_{IN0}, V_{IN1}, V_{IN2} is input to the gates of TSG0, TSG1, TSG2, respectively, and the operation data (output data or output vector) I_{D0}, I_{D1}, I_{D2} is output from bit lines BL0, BL1 and BL2, respectively.

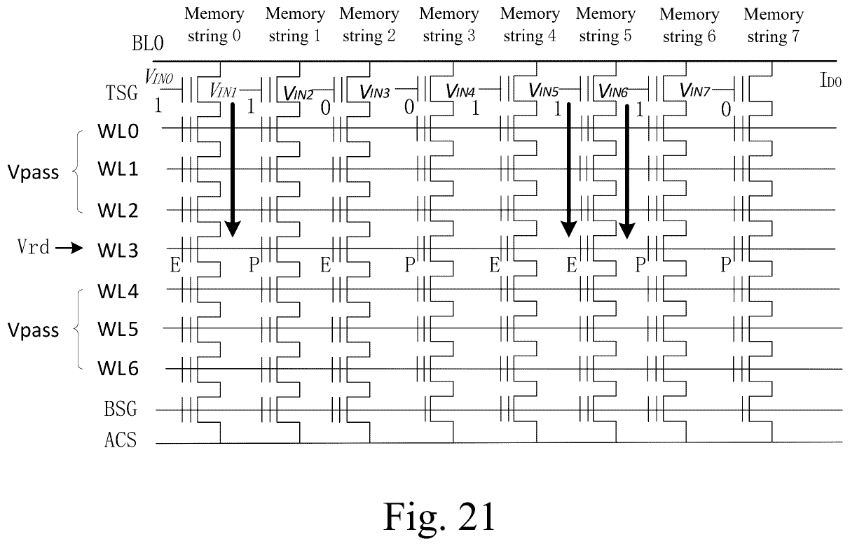

FIG. 21 shows the basic principle of a compute-in-memory operation. As shown in FIG. 21, seven word lines WL of WL0, WL1, WL2, WL3, WL4, WL5 and WL6, and eight memory strings (str) of memory string 0 (str0), memory string 1 (str1), memory string 2 (str2), memory string 3 (str3), memory string 4 (str4), memory string 5 (str5), memory string 6 (str6) and memory string 7 (str7) in the array of memory cells 601 are shown.

The memory cell may be, but is not limited to, configured as SLC, MLC, TLC and QLC memory cells, and the example takes the memory cell for storing the weight array data being configured to be an SLC memory cell as an example, that is, each memory cell may have two states, an erase state E, or a program state P. The erase state E may indicate that the data stored in the current memory cell is 1, denoted as E (1). The program state P may indicate that the data stored in the current memory cell is 0, denoted as P (0).

As shown in Table 1, the relationship between the input operation data (Vin), the weight data in the memory cell (e.g., the threshold voltage Vth of the memory cell), and the operation result (such as the bit line (BL) current) output from the array of memory cells 601 is shown.

TABLE 1

| Operation | Weight Data | Operation Results |
|---|---|---|
| Data (Vin) | (Weight) | (output) |
| 1 | E(1) | 1 |
| 1 | P(0) | 0 |
| 0 | E(1) | 0 |
| 0 | P(0) | 0 |

During the compute-in-memory operation, the read voltage Vrd is applied on the selected word line WL (the program word line, on which the memory cell stores the weight data) to activate the weight data stored in the memory cell coupled to the selected word line WL, and the turn-on voltage Vpass is applied to the other WLs. An input voltage (operation data or input vector) is applied on the top select gate TSG. The output current is collected at the BL, and after the output currents of all the memory cells are collected, the addition is achieved through accumulation.

In an example, as shown in FIG. 21, taking the weight data stored in the memory cell of the word line WL3 being E(1), P(0), E(1), P(0), E(1), E(1), P(0), and P(0) as an example. If a read voltage Vrd is applied to the word line WL3 in the array of memory cells 601 as shown in FIG. 21, the input voltage V_{IN0}=1, V_{IN1}=1, V_{IN2}=0, V_{IN3}=0, V_{IN4}=1, V_{IN5}=1, V_{IN6}=1, V_{IN7}=1 are applied to the top select gate TSG, then

$${I}_{D 0} = 1 * E ( 1 ) + 1 * P ( 0 ) + 1 * E ( 1 ) + 1 * P ( 0 ) + 1 * E ( 1 ) + 1 * E ( 1 ) + 1 * P ( 0 ) + 1 * P ( 0 )$$

Therefore, the process of performing the vector matrix multiply and addition operation on the compute-in-memory device is equivalent to the operations of applying voltage and reading current in the array of memory cells 601. The memory string 0, memory string 4, memory string 5 contribute current in the current I_{D0}.

In some implementations, in the semiconductor device 600 shown in FIG. 18, in order to avoid address conflict and data obfuscation, a physical address range mapped to memory blocks in the storage zone S and the compute-in-memory zone C is set to be different and have no intersection, to ensure data integrity and security, and improve system stability.

In some examples, the peripheral circuit 602 receives at least one of a first address information or a second address information, wherein the first address information and the second address information may be sent by the controller 11200 in FIG. 1, FIG. 3, or FIG. 4, or may be sent by the host 12000 in FIG. 2, which is not limited herein. In addition, the first address information is configured to determine a position of a target memory bank in the compute-in-memory zone C, and the second address information is configured to determine a position of a target memory block in the storage zone S.

The peripheral circuit 602 may control the target memory bank in the compute-in-memory zone C to perform a compute-in-memory operation according to the first address information, wherein the target memory bank is a memory bank in the compute-in-memory zone C. Similarly, the peripheral circuit 602 may control the target memory block in the storage zone S to perform the memory operation according to the second address information.

In an example, the first address information is further configured to determine positions of the target memory bank and the target memory block. The peripheral circuit 602 may control a target memory block in the target memory bank to perform the compute-in-memory operation according to the first address information.

In some implementations, for a plurality of memory banks in the compute-in-memory zone C, when a number of faulty memory blocks in the memory bank is greater than a threshold, the memory bank may be marked as a faulty memory bank and no longer configured to perform a compute-in-memory operation. However, in order to avoid causing space waste in the array of memory cells 601, the memory bank in which the number of faulty memory blocks is greater than a threshold may be configured as a storage zone S and is configured to perform a memory operation, to increase a space utilization rate in the array of memory cells 601.

In some examples, when the number of faulty memory blocks in the target memory bank corresponding to the first address information is greater than the threshold, the target memory bank is configured as the storage zone S, and the peripheral circuit 602 may control the target memory bank to perform the memory operation according to the first address information.

In some examples, when a first number of memory blocks in the plurality of memory blocks of the memory bank is configured as the working memory blocks, and a second number of memory blocks is configured as the extra memory blocks, the second number may be used as the threshold, that is, the memory bank of the plurality of memory banks in which the number of faulty memory blocks is greater than the second number is configured as the storage zone S.

In an example, when the first address information is further configured to determine the positions of the target memory bank and the target memory block, and the number of target memory blocks is less than the first number or the number of faulty memory blocks is greater than the second number, the peripheral circuit 602 may control the target memory block in the target memory bank to perform the memory operation according to the first address information.

During the use of the semiconductor device 600 as shown in FIG. 18, there are at least two related data operations, one is to refresh the data stored in the compute-in-memory zone C, and the other is to perform garbage collection on the data stored in the compute-in-memory zone C.

In some implementations, the data stored in the compute-in-memory zone C is refreshed. For the semiconductor devices 600, such as NAND, taking NAND as an example, NAND is a non-volatile memory. As shown in FIG. 8, the memory cell 606 may be a charge trapping type of memory cell, which may include a gate 606-G, a charge block layer 310, a charge trap layer 320, a tunnel layer 330, and a channel layer 340, and store data by changing the amount of charge in the charge trap layer 320.

When performing a program operation on the memory cell 606, the charge trap layer 320 may trap charges from the channel layer 340 and through the tunnel layer 330 according to the tunneling effect under the control of the voltage of the gate 606-G, and the electrons are injected into the charge trap layer 320 to form a certain charge distribution, so that the memory cell 606 has different threshold voltages and is in different program states.

When the data is read, the stored data is determined by detecting the threshold voltage of the memory cell 606.

However, when the memory cell 606 in the semiconductor device 600 is not accessed for a long time, the charge on the charge trap layer 320 may gradually decrease due to leakage. Because of the influence of charge leakage and other physical factors, the data retention capability of the semiconductor device 600 may gradually decrease, resulting in a change in the threshold voltage of the memory cell 606, thereby affecting the accuracy, stability and reliability of the data.

In order to improve the accuracy, stability and reliability of data, the memory cell 606 may be periodically refreshed to re-inject charge, so as to restore its target threshold voltage.

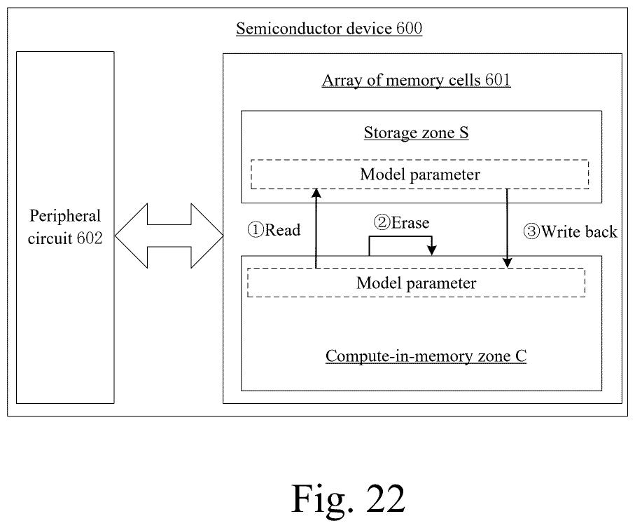

In an implementation, taking the semiconductor structure 600 as shown in FIG. 18 as an example, as shown in FIG. 22, data in the compute-in-memory zone C, such as model parameter or weight data, is read and written into the storage zone S. The data in the compute-in-memory zone C is erased, the data in the storage zone S is read and written back to the compute-in-memory zone C.

It should be noted that, in the process of refreshing the data in the memory cell 606, it may be refreshed at a level of the memory bank, and the position where the data is read in the compute-in-memory zone C may be the same as the position where the data is written back, or different from the position where the data is written back (that is, the data is updated in different places).

In an example, the data of the first memory bank in the compute-in-memory zone C is read and written into the storage zone S. The data of the first memory bank in the compute-in-memory zone C is erased, and the data in the storage zone S is read and written into the first memory bank of the compute-in-memory zone C. For example, taking the data of the first memory bank being the model parameter as an example, the model parameter stored in the compute-in-memory zone C is read and temporarily written into the storage zone S first, then the model parameter stored in the compute-in-memory zone C is erased, and finally the related model parameter is written back into the original physical address space in the compute-in-memory zone C from the storage zone S.

In an example, refreshing the data stored in the compute-in-memory zone C includes a data reading phase, a data erasing phase, and a data writing-back phase.

The data reading phase: firstly, data are read from a memory block in a first memory bank at a level of a memory page, and then, the read data are written into the storage zone S. The above operations are repeated until the data in all the memory blocks in the first memory bank are completely written into the storage zone S.

The data erasing phase: after the data are successfully written into the storage zone S, then the original data of the first memory bank in the compute-in-memory zone C are erased at a level of a memory block. This operation is to prepare to re-write the updated data back into the first memory bank, and at the same time ensure that the data in the compute-in-memory zone C are the latest and consistent.

The data writing-back phase: the previously written data are read from the storage zone S, and these data are written back to the corresponding memory block in the first memory bank at a level of a memory page. The above operations are repeated until all data in the storage zone S are completely written back into the first memory bank.

Through the above implementation, the reliability and the retention of the written data (such as the key information such as the neural network model parameters) in the compute-in-memory zone C can be effectively improved, so as to meet the requirement of the compute-in-memory zone C on the data reliability when performing the compute-in-memory operation.

In another example, the data of the first memory bank in the compute-in-memory zone C are read and written into the storage zone S. The data of the second memory bank in the compute-in-memory zone C are erased, the data in the storage zone S are read, and written into the second memory bank of the compute-in-memory zone C, wherein the first memory bank may be different from the second memory bank, that is, the data is updated in different places. Wear leveling can be achieved by updating the data in different places, e.g., the lifetime of the semiconductor device 600 can be extended by uniformly using all cells in the semiconductor device 600. By updating the data in different places, the semiconductor device 600 may transfer the data from blocks with more wear into blocks with less wear, thereby balancing the extent of wear of each block.

In an example, performing garbage collection on the data stored in the compute-in-memory zone C also includes a data reading phase, a data erasing phase, and a data writing-back phase.

The data reading phase: firstly, valid data are read from a memory block in a first memory bank at a level of a memory page, and then, the read valid data are written into the storage zone S. The above operations are repeated until the valid data in all the memory blocks in the first memory bank are completely written into the storage zone S.

The data erasing phase: after the valid data in the first memory bank are successfully written into the storage zone S, then the original data of the second memory bank in the compute-in-memory zone C are erased at a level of a memory block. This operation is to prepare to re-write the read valid data back into the second memory bank.

The data writing-back phase: the previously written valid data are read from the storage zone S, and these valid data are written back into the corresponding block in the second memory bank at a level of a memory page. The above operations are repeated until all valid data in the storage zone S are completely written back into the second memory bank.

In the above implementation, the data stored in the compute-in-memory zone C are read and temporarily written into the storage zone S having the longer lifetime. This operation is equivalent to backing up the data stored in the compute-in-memory zone C. Next, the related data temporarily stored in the storage zone S are re-written back to the corresponding physical address space (for example, the original physical address space or another physical address space) in the compute-in-memory zone C. According to the implementation, a “refresh” operation is performed on the memory cells in the compute-in-memory zone C, so that the change of the threshold voltage of the memory cell caused by the factors such as charge leakage can be corrected, thereby reducing the error rate of the compute-in-memory zone C in reading data, improving the accuracy and reliability of the data, and effectively prolonging the retention characteristic of the data in the compute-in-memory zone C.

In some implementations, the garbage collection is performed on the data stored in the compute-in-memory zone C. In the compute-in-memory zone C, the weight data will also be all or partially updated during performing the compute-in-memory operation. The weight data is partially updated, that is, the original weight data includes valid data and invalid data, the valid data is configured to perform the compute-in-memory operation, and the invalid data needs to be updated to new weight data. In this scenario, the semiconductor device 600 needs to recover space occupied by invalid data, thereby releasing more storage space for new data usage, so as to manage the storage space more effectively.

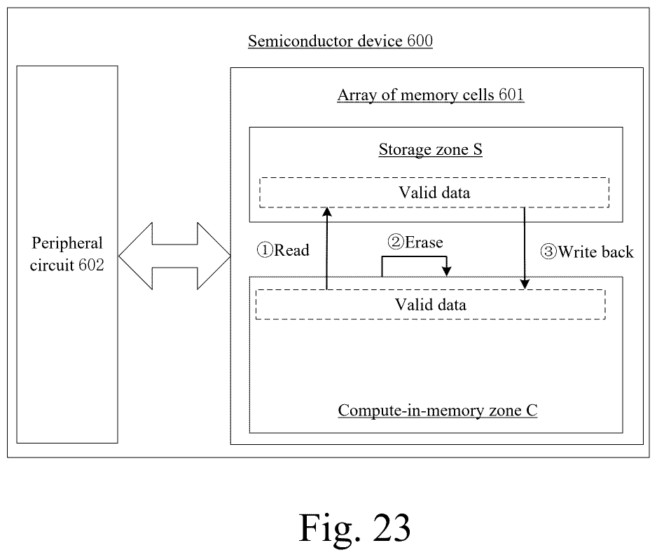

In some examples, as shown in FIG. 23, the valid data in the compute-in-memory zone C are read and written into the storage zone S. The data in the compute-in-memory zone C are erased. The valid data temporarily stored in the storage zone S are read and written into the compute-in-memory zone C.

In the above example, the memory blocks in the semiconductor device 600 are configured into the storage zone S and the compute-in-memory zone C, and the storage zone S is dedicated to storing temporary data in the garbage collection process. As a result, the number of times of erasing (PE) that can be born by the memory block in the storage zone S will far exceed that required by the compute-in-memory zone C, so that the lifetime of the storage zone S can be prolonged, and the writing amount thereof can be improved.

It should be noted that, in the process of performing the garbage collection on the data in the memory cell 606, the collection may be performed at level of a memory bank, and the position of the valid data read in the compute-in-memory zone C may be the same as that of the valid data that are written back, or different from that of the valid data that are written back (that is, performing the data collection in different places).

In an example, the valid data of the first memory bank in the compute-in-memory zone C are read and written into the storage zone S. The data of the first memory bank in the compute-in-memory zone C are erased, and the valid data in the storage zone S are read and written into the first memory bank of the compute-in-memory zone C. For example, taking the data of the first memory bank being the model parameters as an example, the valid data in the model parameters stored in the compute-in-memory zone C are read, and temporarily written into the storage zone S, and then the model parameters stored in the compute-in-memory zone C are erased, and finally the related valid data are written back into the original physical address space in the compute-in-memory zone C from the storage zone S.

In another example, the valid data of the first memory bank in the compute-in-memory zone C are read and written into the storage zone S. The data of the second memory bank in the compute-in-memory zone C are erased, and the valid data in the storage zone S are read and written into the second memory bank of the compute-in-memory zone C. The first memory bank may be different from the second memory bank, that is, performing the data collection in different places. Wear leveling can be achieved by the data collection in different places, e.g., the lifetime of the semiconductor device 600 can be extended by uniformly using all cells in the semiconductor device 600. Through the garbage collection, the semiconductor device 600 may transfer the data from blocks with more wear into blocks with less wear, thereby balancing the extent of wear of each block.

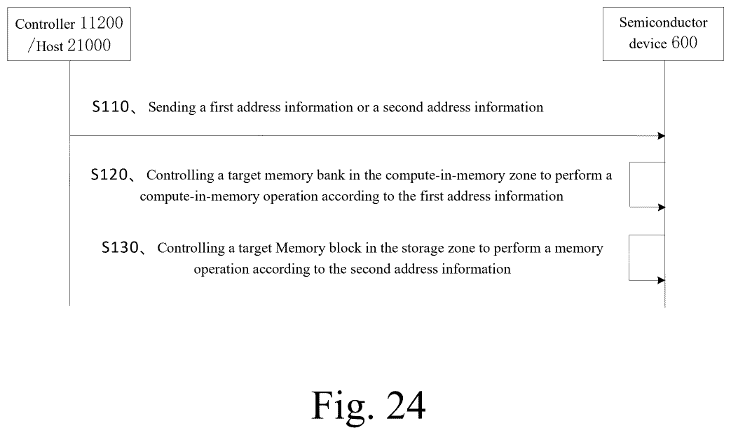

Based on the semiconductor device 600 shown in FIG. 18 and the memory system and the electronic device applying the semiconductor device 600 shown in FIG. 18, the first operating method including the following operations S110-S130 may be implemented as shown in FIG. 24, and the operations include:

S110: sending a first address information or a second address information.

In some examples, the first address information and the second address information may be sent by the controller 11200 in FIG. 1, FIG. 3, or FIG. 4, or may be sent by the host 12000 in FIG. 2, which is not limited herein. In addition, the first address information is configured to determine a position of a target memory bank in the compute-in-memory zone C, and the second address information is configured to determine a position of a target memory block in the storage zone S.

In some examples, the first address information is further configured to determine positions of the target memory bank and the target memory block.

S120: controlling a target memory bank in the compute-in-memory zone to perform a compute-in-memory operation according to the first address information.

For a detailed process of performing the compute-in-memory operation, refer to the examples shown in FIG. 19, FIG. 20 and FIG. 21, and details are not described herein again.

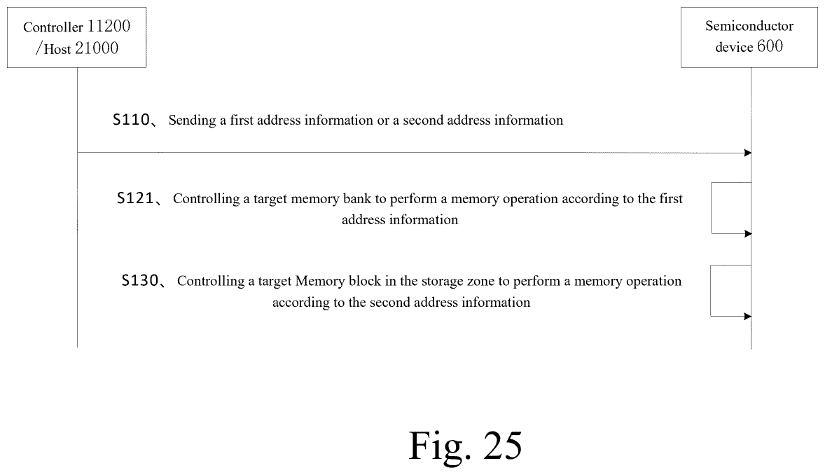

As shown in FIG. 25 and the foregoing examples, when a number of faulty memory blocks in a target memory bank corresponding to the first address information is greater than a threshold, the target memory bank is configured as a storage zone S, and the semiconductor device 600 is configured to perform S121:

S121: controlling a target memory bank to perform a memory operation according to the first address information.

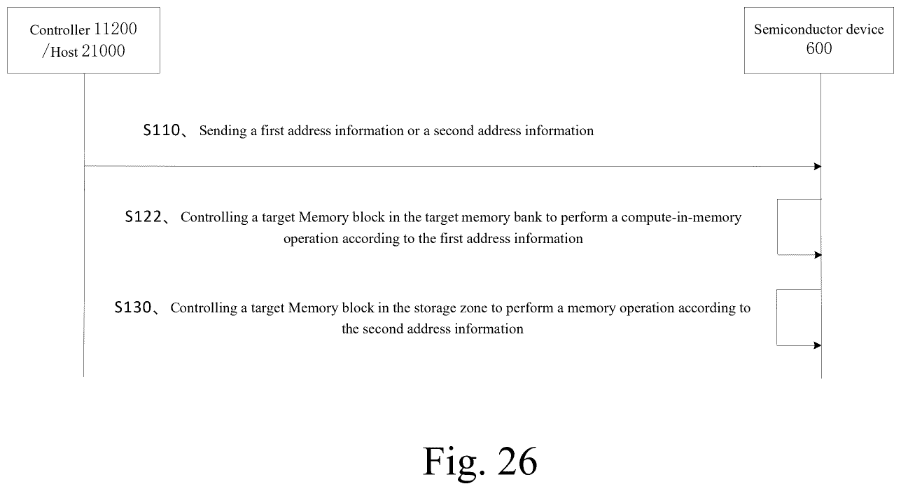

As shown in FIG. 26 and the foregoing examples, when the first address information is further configured to determine the positions of the target memory bank and the target memory blocks, the semiconductor device 600 is configured to perform S122:

S122: controlling the target memory blocks in the target memory bank to perform a compute-in-memory operation according to the first address information.

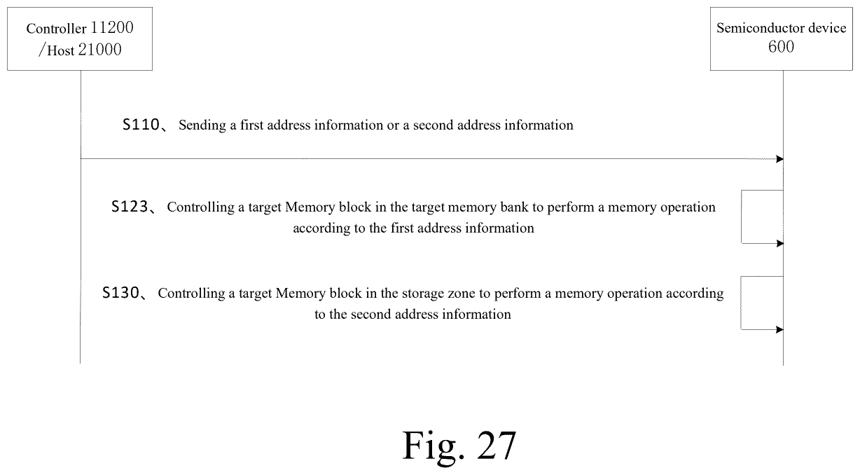

As shown in FIG. 27 and the foregoing examples, when the first address information is further configured to determine the positions of the target memory bank and the target memory blocks, and the number of the target memory blocks is less than a first number or the number of the faulty memory blocks is greater than a second number, the semiconductor device 600 is configured to perform S123:

S123: controlling the target memory blocks in the target memory bank to perform a memory operation according to the first address information.

S130: controlling the target memory blocks in the storage zone to perform a memory operation according to the second address information.

The memory operation may include data writing, reading, and erasing, which may refer to the foregoing examples, and details are not described herein again.

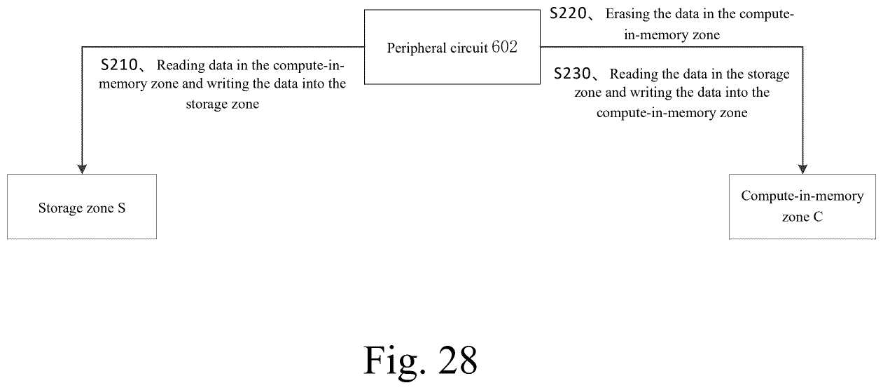

Based on the foregoing semiconductor device 600 shown in FIG. 18 and the memory system and the electronic device applying the semiconductor device 600 shown in FIG. 18, a second operating method including the following operations S210-S230 may be implemented as shown in FIG. 28, and the second operating method may be performing a refresh operation on the data stored in the compute-in-memory zone C as shown in FIG. 22, and the operations include:

S210: reading data in the compute-in-memory zone and writing the data into the storage zone.

S220: erasing the data in the compute-in-memory zone.

S230: reading the data in the storage zone and writing the data into the compute-in-memory zone.

For a implementation process of operation S210 to operation S230, refer to the example shown in FIG. 22, and details are not described herein again.

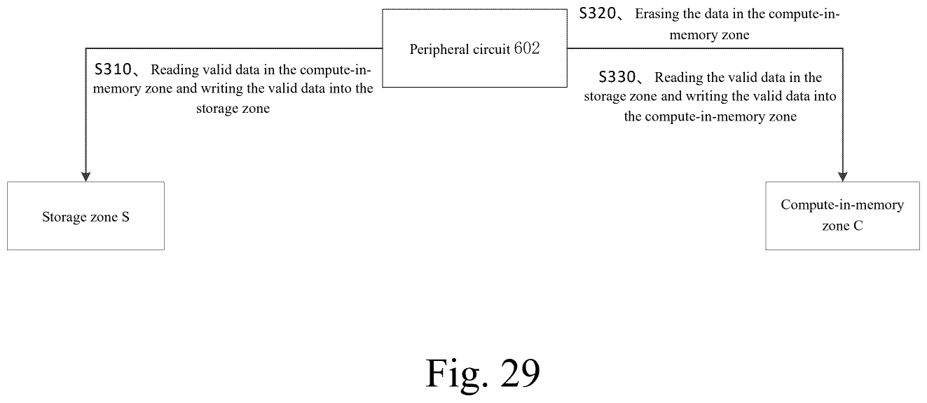

Based on the foregoing semiconductor device 600 shown in FIG. 18 and the memory system and the electronic device applying the semiconductor device 600 shown in FIG. 18, a third operating method including the following operations S310-S330 may be implemented as shown in FIG. 29, and the third operating method may be performing a garbage collection operation on the data stored in the compute-in-memory zone C as shown in FIG. 23, and the operations include:

S310: reading valid data in the compute-in-memory zone and writing the valid data into the storage zone.

S320: erasing the data in the compute-in-memory zones.

S330: reading the valid data in the storage zone and writing the valid data into the compute-in-memory zone.

For a implementation process of operation S310 to operation S330, refer to the example shown in FIG. 23, and details are not described herein again.

An example of the present disclosure further provides a computer-readable storage medium including an instruction. The instruction, when executed on the electronic device or the memory system described in the above examples, causes the electronic device or the memory system to perform the operating method of the semiconductor device as described in the above examples.

An example of this application further provides a system, which can include the controller in FIG. 1, FIG. 3, or FIG. 4, and the semiconductor device shown in FIG. 1, FIG. 2, FIG. 3, or FIG. 4.

The above descriptions are only implementations of the present disclosure, but the protection scope of the present disclosure is not limited thereto, and changes or replacements that may be easily conceived by any person skilled in the art within the technical scope of the present disclosure should be covered within the protection scope of the present disclosure. Therefore, the protection scope of the present disclosure should be defined by the protection scope of the claims.

What is claimed is:

1. A semiconductor device, comprising:
a peripheral circuit; and
an array of memory cells coupled with the peripheral circuit, comprising:
a storage zone; and
a compute-in-memory zone comprising a plurality of memory banks,
wherein the storage zone and any one of the memory banks comprise a plurality of memory blocks;
wherein the plurality of memory banks are configured to perform a compute-in-memory operation; and
wherein the plurality of memory blocks in the storage zone are configured to perform a memory operation.

2. The semiconductor device according to claim 1, wherein physical address ranges mapped to the memory blocks in the storage zone and the compute-in-memory zone are different and have no intersection.

3. The semiconductor device according to claim 1, wherein the peripheral circuit is configured to:
configure a memory bank of the plurality of memory banks whose faulty memory blocks have a number greater than a threshold as the storage zone.

4. The semiconductor device according to claim 3, wherein the peripheral circuit is configured to:
control a target memory bank in the compute-in-memory zone to perform the compute-in-memory operation according to a first address information, wherein the first address information is configured to determine a position of the target memory bank; and
control a target memory block in the storage zone to perform the memory operation according to a second address information, wherein the second address information is configured to determine a position of the target memory block.

5. The semiconductor device according to claim 4, wherein the peripheral circuit is configured to:
control the target memory bank to perform the memory operation according to the first address information when the number of the faulty memory blocks in the target memory bank is greater than the threshold.

6. The semiconductor device according to claim 1, wherein the peripheral circuit is configured to:
configure a first number of memory blocks in the plurality of memory blocks of the memory bank as working memory blocks, and configure a second number of memory blocks as extra memory blocks.

7. The semiconductor device according to claim 6, wherein the peripheral circuit is configured to:
configure a memory bank of the plurality of memory banks whose faulty memory blocks have a number greater than the second number as the storage zone.

8. The semiconductor device according to claim 6, wherein the peripheral circuit is configured to:
control target memory blocks in a target memory bank to perform the compute-in-memory operation according to a first address information, and
wherein the target memory bank is a memory bank in the compute-in-memory zone; a number of the target memory blocks is the first number; and the first address information is configured to determine positions of the target memory bank and the target memory blocks.

9. The semiconductor device according to claim 8, wherein the peripheral circuit is configured to:
control the target memory blocks in the target memory bank to perform the memory operation according to the first address information when the number of the target memory blocks is less than the first number.

10. The semiconductor device according to claim 1, wherein the peripheral circuit is configured to:
read data in the compute-in-memory zone and write the data into the storage zone;
erase the data in the compute-in-memory zone; and
read the data in the storage zone and write the data into the compute-in-memory zone.

11. The semiconductor device according to claim 10, wherein the data in the compute-in-memory zone comprise valid data configured to perform the compute-in-memory operation, and the peripheral circuit is configured to:
read the valid data in the compute-in-memory zone and write the valid data into the storage zone;
erase the data in the compute-in-memory zone; and
read the valid data in the storage zone and write the valid data into the compute-in-memory zone.

12. A method of operating a semiconductor device, comprising:
controlling a target memory bank in a compute-in-memory zone to perform a compute-in-memory operation according to a first address information, wherein the first address information is configured to determine a position of the target memory bank; and
controlling a target memory block in a storage zone to perform a memory operation according to a second address information, wherein the second address information is configured to determine a position of the target memory block.

13. The method according to claim 12, wherein physical address ranges mapped to memory blocks in the storage zone and the compute-in-memory zone are different and have no intersection.

14. The method according to claim 12, further comprising:
controlling the target memory bank to perform the memory operation according to the first address information when a number of faulty memory blocks in the target memory bank is greater than a threshold.

15. The method according to claim 12, further comprising:
reading data in the compute-in-memory zone and writing the data into the storage zone;
erasing the data in the compute-in-memory zone; and
reading the data in the storage zone and writing the data into the compute-in-memory zone.

16. The method according to claim 15, wherein the data in the compute-in-memory zone comprises valid data configured to perform the compute-in-memory operation, and the method further comprises:
reading the valid data in the compute-in-memory zone and writing the valid data into the storage zone;
erasing the data in the compute-in-memory zone; and
reading the valid data in the storage zone and writing the valid data into the compute-in-memory zone.

17. The method according to claim 12, wherein a number of faulty memory blocks in the target memory bank of the compute-in-memory zone is less than a threshold.

18. The method according to claim 12, wherein the target memory bank of the compute-in-memory zone comprises a first number of working memory blocks and a second number of extra memory blocks.

19. The method according to claim 18, wherein a number of faulty memory blocks in the target memory bank of the compute-in-memory zone is less than the second number.

20. A system, comprising:
a controller; and
a semiconductor device coupled to the controller, the semiconductor device comprising:
a peripheral circuit; and
an array of memory cells coupled with the peripheral circuit, comprising:
a storage zone; and
a compute-in-memory zone comprising a plurality of memory banks,
wherein the storage zone and any one of the memory banks comprise a plurality of memory blocks;
wherein the plurality of memory banks are configured to perform a compute-in-memory operation; and
wherein the plurality of memory blocks in the storage zone are configured to perform a memory operation.
